(19) United States
(12) Patent Application Publication
(10) Pub. No.: US 2026/0107539 A1
(43) Pub. Date: Apr. 16, 2026

(54) SEMICONDUCTOR DEVICE AND MANUFACTURING METHOD THEREOF

(71) Applicant: Taiwan Semiconductor Manufacturing Co., Ltd., Hsinchu (TW)

(72) Inventors: Ta-Chun Lin, Hsinchu (TW); Ming-Heng Tsai, Taipei City (TW); Hong-Chih Chen, Changhua County (TW); Jhon Jhy Liaw, Hsinchu County (TW)

(21) Appl. No.: 18/915,968

(22) Filed: Oct. 15, 2024

(51) Int. Cl. H01L 21/28; H01L 21/822; H01L 21/8238; H01L 27/092; H01L 29/06; H01L 29/417; H01L 29/423; H01L 29/49; H01L 29/66; H01L 29/775; H01L 29/786

(52) U.S. Cl. CPC H10D 64/01326; H10D 30/014; H10D 30/43; H10D 30/6729; H10D 30/6735; H10D 30/6739; H10D 30/6757; H10D 62/121; H10D 64/017; H10D 84/017; H10D 84/0177; H10D 84/0186; H10D 84/0188; H10D 84/038; H10D 84/856; H10D 88/01

(57) ABSTRACT

A method for manufacturing a semiconductor device is provided. The method includes forming an epitaxial stack over a substrate, the epitaxial stack comprising at least one first semiconductor layer, at least one first sacrificial layer, at least one second semiconductor layer, and at least one second sacrificial layer; replacing the dummy gate structure, the at least one first sacrificial layer, and the at least one second sacrificial layer with a high-k/metal gate structure; and performing a planarization process on the high-k/metal gate structure, such that a first portion of the high-k/metal gate structure over the at least one second semiconductor layer has a height less than a height of a second portion of the high-k/metal gate structure between the at least one first semiconductor layer and the at least one second semiconductor layer.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate schematic views of intermediate stages in the manufacture of a semiconductor device in accordance with some embodiments of the present disclosure.

FIG. 11 is a cross-sectional view of a semiconductor device in accordance with some embodiments of the present disclosure.

FIGS. 12-14 illustrate cross-sectional views of intermediate stages in the manufacture of a semiconductor device in accordance with some embodiments of the present disclosure.

FIG. 15 is a cross-sectional view of a semiconductor device in accordance with some embodiments of the present disclosure.

FIGS. 16-22B illustrate cross-sectional views of intermediate stages in the manufacture of a semiconductor device in accordance with some embodiments of the present disclosure.

FIGS. 23-29 illustrate schematic views of intermediate stages in the manufacture of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

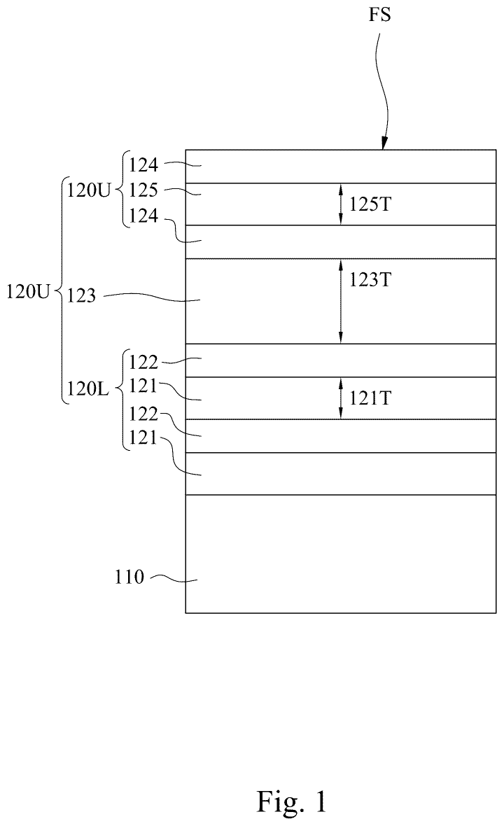

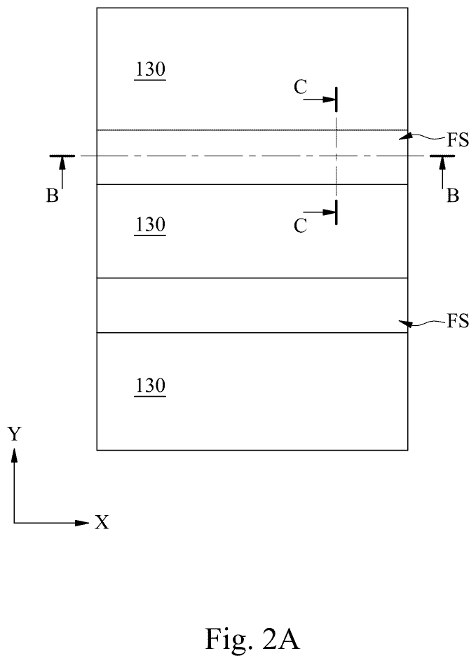

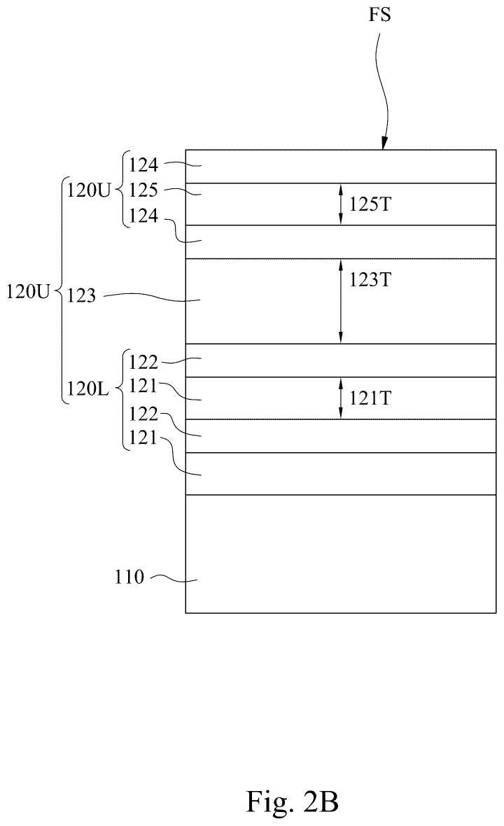

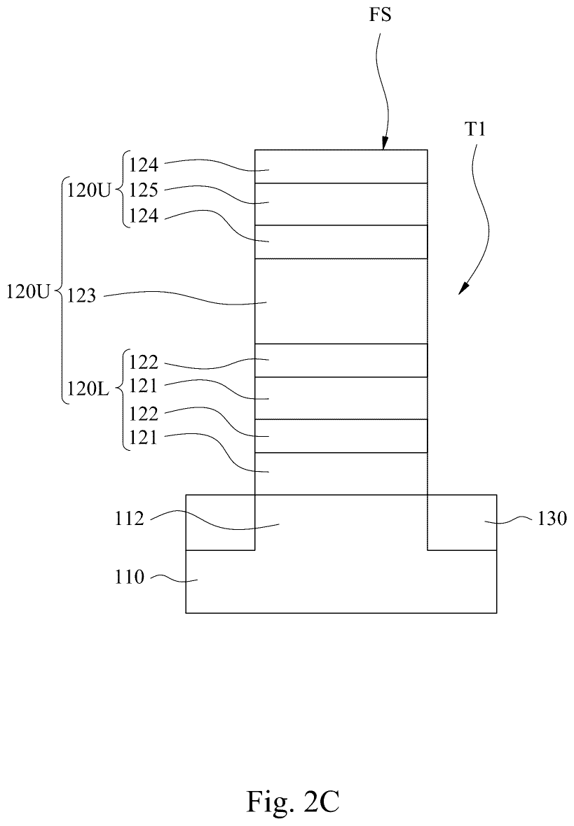

FIGS. 1-10 illustrate schematic views of intermediate stages in the manufacture of a semiconductor device in accordance with some embodiments of the present disclosure. FIGS. 2A, 3A, 5A, 6A, and 7A are top views of the semiconductor device at various manufacturing stages in accordance with some embodiments. FIGS. 1, 2B, 3B, 4, 5B, 6B, 7B, and 8-10 are cross-sectional views of the semiconductor device (e.g., taken along line B-B in FIGS. 2A, 3A, 5A, 6A, and 7A) at various manufacturing stages in accordance with some embodiments. FIGS. 2C, 3C, 6C, and 7C are cross-sectional views of the semiconductor device (e.g., taken along line C-C in FIGS. 2A, 3A, 6A, and 7A) at various manufacturing stages in accordance with some embodiments. It is understood that additional steps may be provided before, during, and after the steps shown in FIGS. 1-10, and some of the steps described below can be replaced or eliminated for additional embodiments of the method. The order of the operations/processes may be interchangeable.

Reference is made to FIG. 1. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes a lower epitaxial stack 120L, an interlayer sacrificial layer 123, and an upper epitaxial stack 120U stacked in a sequence over the substrate 110. The lower epitaxial stack 120L includes lower sacrificial layers 121 and lower channel layers 122 alternately arranged with each other. The upper epitaxial stack 120U includes upper semiconductor layers 124 and upper sacrificial layers 125 alternately arranged with each other. The interlayer sacrificial layer 123 is located between the lower epitaxial stack 120L and the upper epitaxial stack 120U. The sacrificial layers 121, 123, and 125 may have different semiconductor compositions from the channel layers 122 and 124. In some embodiments, the layers 121-125 may include SiGe with various semiconductor compositions. For example, a Si concentration in the sacrificial layers 121, 123, and 125 is less than a Si concentration in the channel layers 122 and 124. Stated differently, in the embodiments, a Ge concentration in the sacrificial layers 121, 123, and 125 is greater than a Ge concentration in the channel layers 122 and 124. For example, the channel layers 122 and 124 are SiₓGe₁₋ₓ, and the sacrificial layers 121, 123, and 125 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 121, 123, and 125 include SiGe and the channel layers 122 and 124 include Si, the Si oxidation rate of the channel layers 122 and 124 is less than the SiGe oxidation rate of the sacrificial layers 121, 123, and 125.

The channel layers 122 and 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 122 and 124 may be referred to as semiconductor channels in the context. The use of the channel layers 122 and 124 to define a channel or channels of a device is further discussed below. In the depicted embodiments, the number of the channel layers 122/124 is two. In various embodiments, the number of the channel layers 122/124 may vary in a range from 1 to 10.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 122 and 124 include suitable semiconductor material, such as like Si, Ge, Sn, SiGe, GeSn, III-V semiconductor, the like, or the combination thereof. In some embodiments, the channel layers 122 and 124 may include a same semiconductor material as that of the substrate 110. In some embodiments, the epitaxially grown sacrificial layers 121, 123, and 125 include a different material than the substrate 110. For example, the sacrificial layers 121, 123, and 125 include suitable semiconductor material, such as Si, Ge, SiGe, GeSn, III-V semiconductor, the like, or the combination thereof. In some other embodiments, at least one of the layers 121-125 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the layers 121-125 may be chosen based on providing differing oxidation and/or etching selectivity properties. In some embodiments, the layers 121-125 are intrinsic semiconductor layers, which are not intentionally doped, for example, not having intentionally placed dopants, but rather having a doping resulting from process contaminants. In some embodiments, the layers 121-125 are substantially dopant-free (i.e., having an extrinsic dopant concentration from about 0 cm⁻³ to about 1×10¹⁸ cm⁻³), where for example, no intentional doping is performed during the epitaxial growth process.

A thickness 121T of the sacrificial layers 121 may determine the spaces between the channel layers 122. A thickness 125T of the sacrificial layers 125 may determine the space between the channel layers 124. A thickness 123T of the sacrificial layers 123 may determine the space between a topmost one of the bottom channel layers 122 and a bottommost one of the top channel layers 124. In some embodiments, the thickness 123T of the sacrificial layers 123 is greater than the thickness 121T of the sacrificial layers 121 and the thickness 125T of the sacrificial layers 125. The thickness 121T of the sacrificial layers 121 may be less than, substantially equal to, or greater than the thickness 125T of the sacrificial layers 125.

Reference is made to FIGS. 2A-2C. A plurality of semiconductor fins FS extending from the substrate 110 are formed. The semiconductor fins FS may extend substantially along a direction X. In various embodiments, each of the fins FS includes a substrate portion 112 formed from the substrate 110 and portions of each of the epitaxial layers of the epitaxial stack 120 including epitaxial layers 121-125. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

The fins FS may be fabricated using suitable processes including photolithography and etch processes. The photolithography process may include forming a photoresist layer (not shown), exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

After the formation of the fins FS, an isolation structure 130 is formed in the trench T1 between the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material into the trench T1, followed by an etching back process. Through the etching back process, a top surface of the isolation structure 130 may be level with or lower than a bottom surface of the epitaxial stack 120. In some alternatively embodiments, the top surface of the isolation structure 130 may be higher than the bottom surface of the epitaxial stack 120.

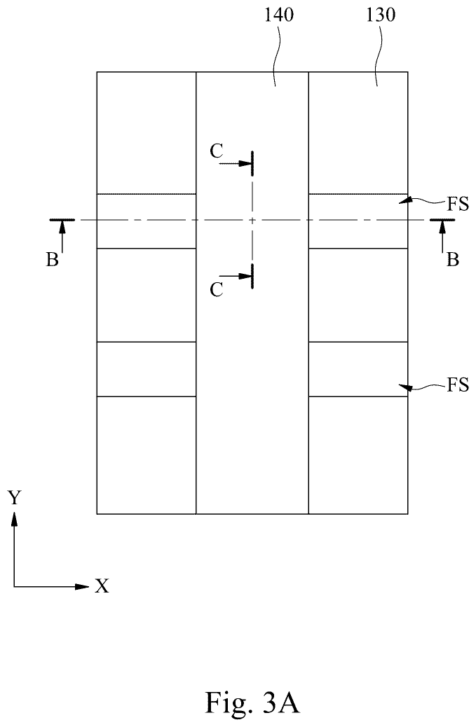

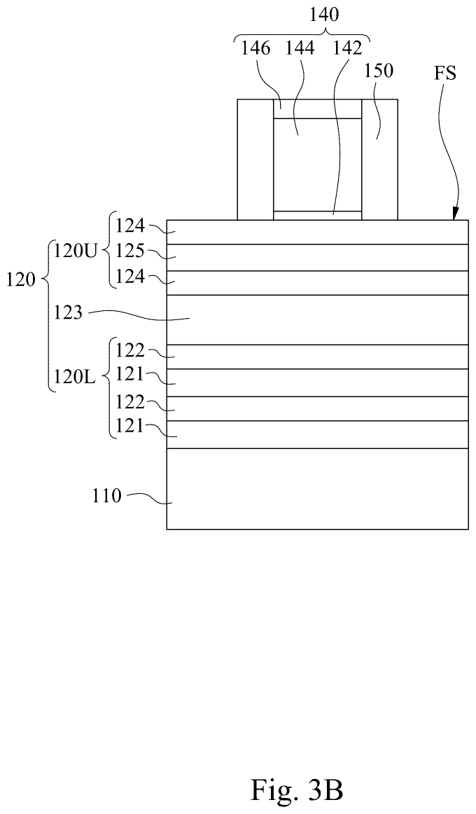

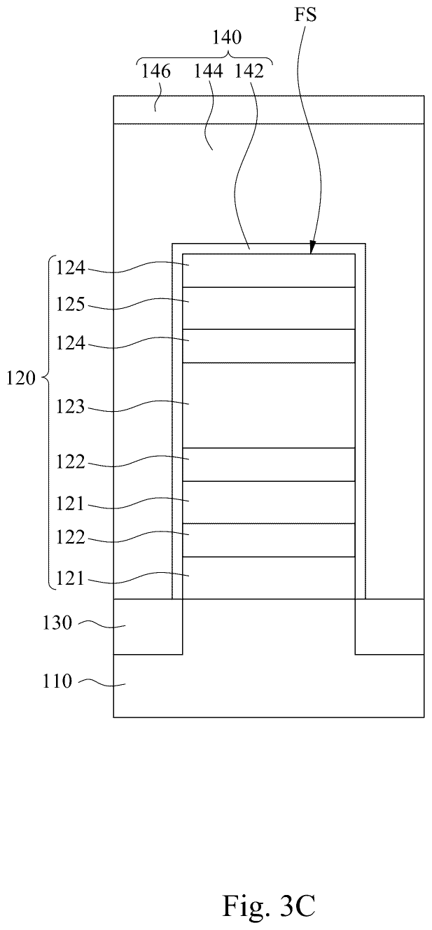

Reference is made to FIGS. 3A-3C. One or more dummy gate structures 140 are formed on the epitaxial stack 120. The dummy gate structure 140 may include a gate dielectric 142, a gate electrode 144, and a hard mask 146. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a CVD process, a sub-atmospheric CVD (SACVD) process, a FCVD process, an ALD process, a PVD process, or other suitable process. The gate electrode 144 may include polycrystalline silicon (polysilicon). The hard mask 146 may include a silicon oxide layer and a silicon nitride layer. In some embodiments, the materials of the dummy gate structures 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 140.

Gate spacers 150 are formed on opposite sidewalls of the dummy gate structures 140. The gate spacer 150 may be made of a dielectric material such as silicon oxide, silicon nitride, silicon carbide, silicon oxynitride, SiCN, silicon oxycarbide, SiOCN, and/or combinations thereof. The gate spacers 150 may be formed by first depositing one or more conformal spacer material layers and subsequently etching back the one or more spacer material layers to form gate spacers 150. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 150 on the vertical surfaces, such as the sidewalls of the dummy gate structures 140.

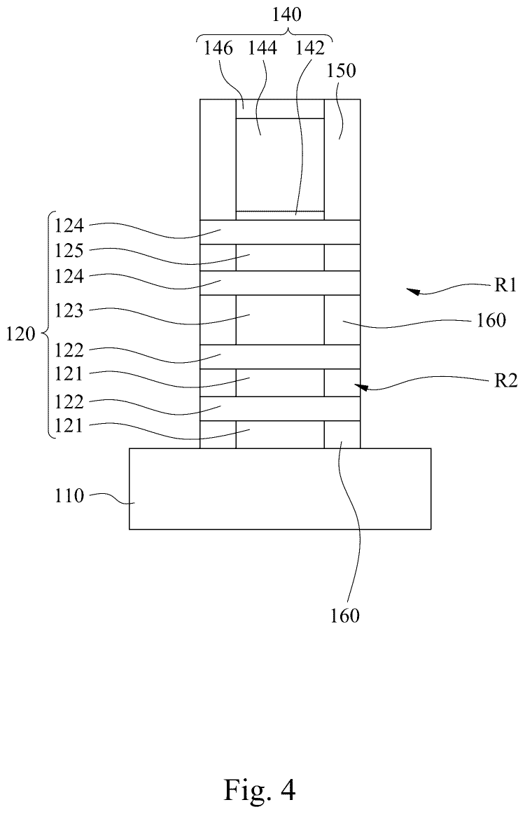

Reference is made to FIG. 4. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS. The recesses R1 may extend through the epitaxial layers 121-125. After the anisotropic etching, end surfaces of the epitaxial layers 121-125 are exposed and aligned with respective outermost sidewalls of the gate spacers 150, due to the anisotropic etching.

The sacrificial layers 121, 123, and 125 are laterally or horizontally recessed by using suitable selective etching process, resulting in lateral/sidewall recesses R2 vertically between corresponding channel layers 122 and 124. For example, end surfaces of the sacrificial layers 121, 123, and 125 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The layers 122 and 124 may have a higher etch resistance to the selective etching process than that of the sacrificial layers 121, 123, and 125. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 122 and 124 may not be significantly etched by the process of laterally recessing the sacrificial layers 121, 123, and 125. As a result, the layers 122 and 124 laterally extend past opposite end surfaces of the sacrificial layers 121, 123, and 125.

Inner spacers 160 are formed in the recesses R2. Stated differently, the inner spacers 160 may be formed on opposite end surfaces of the laterally recessed sacrificial layers 121, 123, and 125. The inner spacers 160 may include a dielectric material, such as SiOₓ, SiON, SiOC, SiN, SiCN, or SiOCN. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 160 may include a single layer or multiple layers. The inner spacers 160 may serve to isolate metal gates from source/drain regions formed in subsequent processing. In the example of FIG. 4, sidewalls of the inner spacers 160 are aligned with sidewalls of the channel layers 122 and 124.

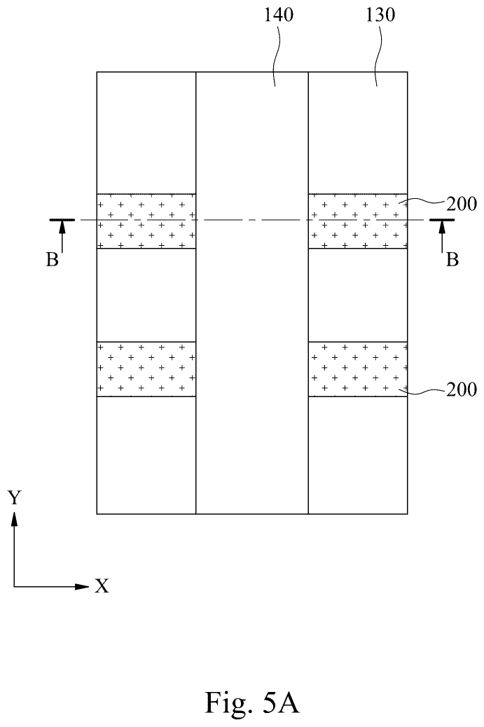

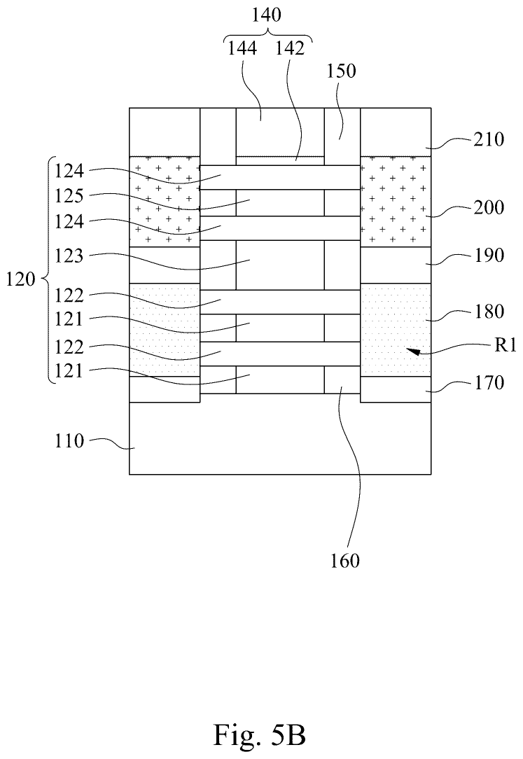

Reference is made to FIGS. 5A and 5B. Source/drain epitaxial structures 180 are formed in the recesses R1 on opposite sides of the channel layers 122 and on opposite sides of the dummy gate structure 140. The source/drain epitaxial structures 180 may be in contact with the exposed end surfaces of the channel layers 122. In some embodiments, the source/drain epitaxial structures 180 may include Ge, Si, GaAs, AlGaAs, SiGe, GaAsP, SiP, or other suitable material. The source/drain epitaxial structures 180 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 180 are not in-situ doped, an implantation process (i.e., a junction implant process) is performed to dope the source/drain epitaxial structures 180. The source/drain epitaxial structures 180 may be formed by performing an epitaxial growth process that provides an epitaxial material on the exposed surfaces of the channel layers 122. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the epitaxial layers 122.

In some embodiments, one or more etching processes may be performed to lower top surfaces of the source/drain epitaxial structures 180. The resulted source/drain epitaxial structures 180 have top surfaces lower than bottom surfaces of the epitaxial layers 124. The etching process may selectively remove a portion of the source/drain epitaxial structures 180 but not the dielectric materials of the gate spacers 150, the hard mask 146 (referring to FIG. 4), and the inner spacers 160. The etching process may be dry etch, wet etch, or the combination thereof.

In some embodiments, prior to the formation of the source/drain epitaxial structures 180, bottom isolation layers 170 are formed in the recesses R1, respectively. In some embodiments, the bottom isolation layer 170 includes SiN, SiO₂, SiON, SiCN, SiCON, SiCO, high-k dielectrics (e.g., HfO, AlO, etc.), other low-k dielectric materials, the like, or the combination thereof. The bottom isolation layer 170 may a single-layer or a multi-layer structure. Formation of the bottom isolation layer 170 may include suitable CVD, ALD process, the like, or the combination thereof. The bottom isolation layer 170 may serve to isolate the source/drain epitaxial structures 180 from the substrate 110. In some alternative embodiments, the bottom isolation layers 170 may be omitted, and the source/drain epitaxial structures 180 are in contact with the substrate 110.

After the formation of the source/drain epitaxial structures 180, middle isolation layers 190 are formed in the recesses R1 and over the source/drain epitaxial structures 180, respectively. The middle isolation layers 190 may include a silicon nitride layer, silicon oxide layer, a silicon oxynitride layer, and/or other suitable materials. In some embodiments, the middle isolation layers 190 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The materials of the middle isolation layers 190 may be deposited into the recess R1 by a CVD process or other suitable deposition technique, followed by an etching process. The etching process may be performed to remove side portions of the dielectric materials of the middle isolation layers 190, leave the end surface of the channel layer 124 exposed.

After the formation of the middle isolation layers 190, source/drain epitaxial structures 200 are formed in the recesses R1 on opposite sides of the channel layers 124 and on opposite sides of the dummy gate structure 140, and over the middle isolation layers 190. The source/drain epitaxial structures 200 may be in contact with the exposed end surfaces of the epitaxial layers 124. In some embodiments, the source/drain epitaxial structures 200 may include Ge, Si, GaAs, AlGaAs, SiGe, GaAsP, SiP, or other suitable material. The source/drain epitaxial structures 200 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 200 are not in-situ doped, an implantation process (i.e., a junction implant process) is performed to dope the source/drain epitaxial structures 200. The source/drain epitaxial structures 200 may be formed by performing an epitaxial growth process that provides an epitaxial material on the exposed surfaces of the channel layers 124. Suitable epitaxial processes include CVD deposition techniques, molecular beam epitaxy, and/or other suitable processes. The epitaxial growth process may use gaseous and/or liquid precursors, which interact with the composition of semiconductor materials of the epitaxial layers 124.

In some embodiments of the present disclosure, for forming a complementary field-effect transistor (CFET), the source/drain epitaxial structures 180 and 200 are of opposite conductivity types. For example, the source/drain epitaxial structures 180 are p-type doped epitaxial features, while the source/drain epitaxial structures 200 are n-type doped epitaxial features. In some alternative embodiments, the source/drain epitaxial structures 180 are n-type doped epitaxial features, while the source/drain epitaxial structures 200 are p-type doped epitaxial features. In some embodiments of the present disclosure, the channel layers 122 and 124 are of opposite conductivity types. For example, the channel layers 122 are lightly doped with n-type dopants as n-type wells, while the channel layers 124 are lightly doped with p-type dopants as p-type wells.

After the formation of the source/drain epitaxial structures 200, a dielectric material 210 is formed over the substrate 110 and filling the space around the dummy gate structures 140. In some embodiments, the dielectric material 210 includes a contact etch stop layer (CESL) and an interlayer dielectric (ILD) layer formed in sequence. In some examples, the CESL layer includes a silicon nitride layer, silicon oxide layer, a silicon oxynitride layer, and/or other suitable. The ILD layer is then deposited over the CESL layer. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL layer. The ILD layer may be deposited by a CVD process or other suitable deposition technique. In some embodiments, after formation of the ILD layer, the semiconductor device may be subject to a high thermal budget process to anneal the ILD layer. After depositing the ILD layer, a planarization process may be performed to remove excessive materials of the ILD layer. For example, a planarization process includes a chemical mechanical polish (CMP) process which removes portions of the dielectric material 210 overlying the dummy gate structures 140 and planarizes a top surface of the semiconductor device. The planarization process may also remove the hard mask 146 (referring to FIG. 4), which leaves the dummy gate electrode 144 exposed.

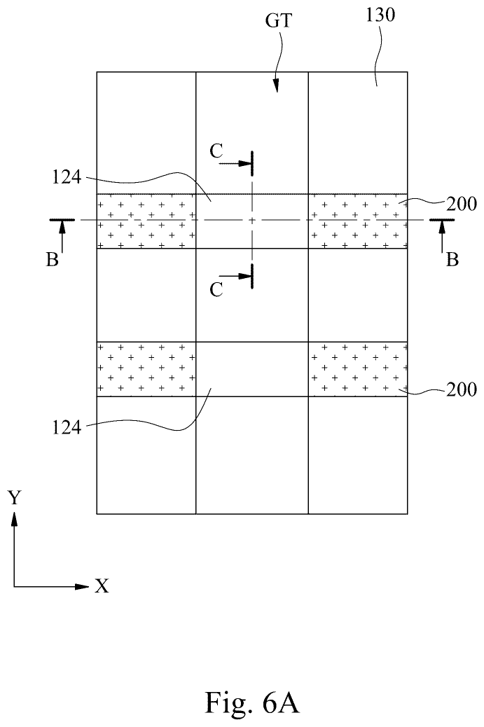

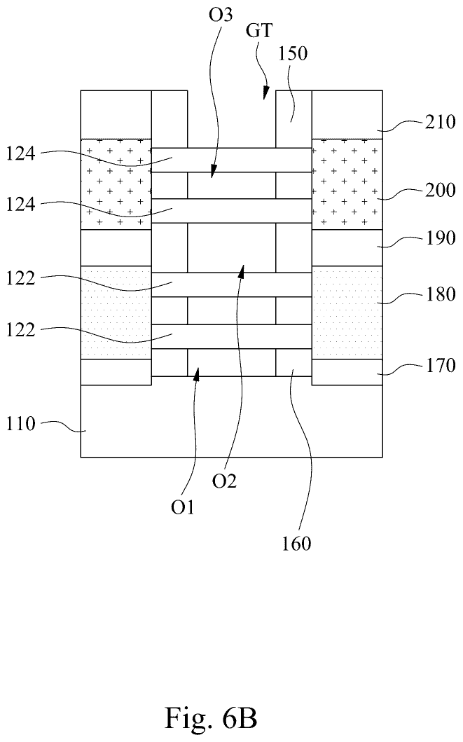

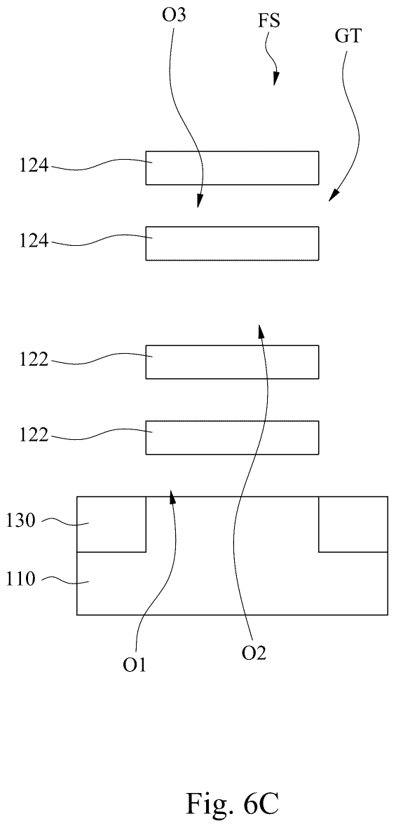

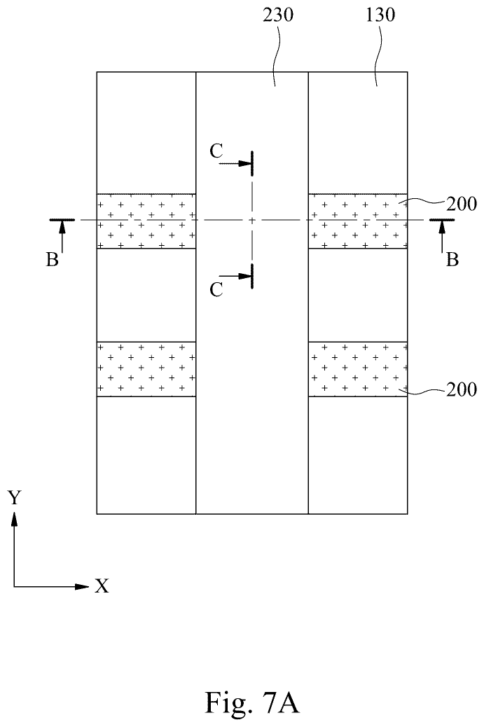

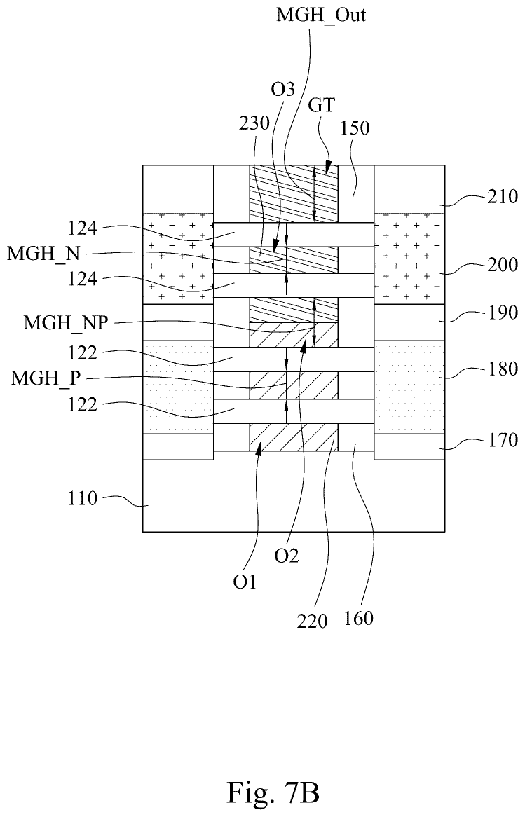

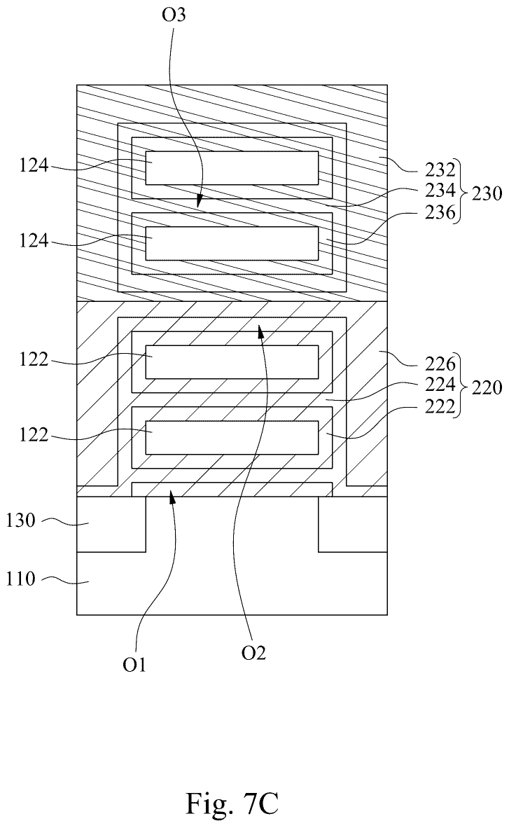

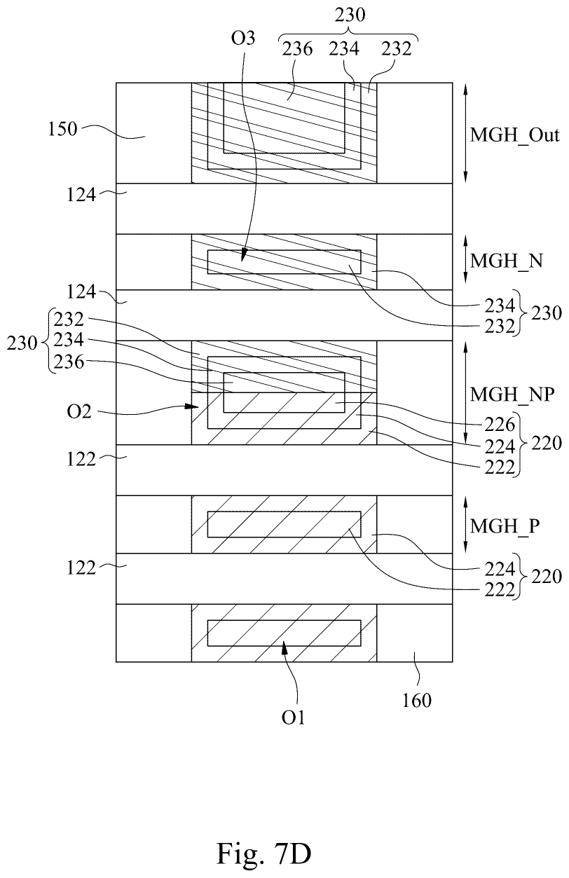

Reference is made to FIGS. 6A-7D. The dummy gate structure 140 and the sacrificial layer 121, 123, and 125 (referring to FIG. 5B) are replaced with high-k/metal gate structures 220 and 230. In FIGS. 6A-6C, the dummy gate structure 140 (referring to FIG. 5B) is removed, followed by removing the sacrificial layers 121, 123, and 125 (referring to FIG. 5B). In the illustrated embodiments, the dummy gate structure 140 (referring to FIG. 5B) is removed by using a selective etching process (e.g., selective dry etching, selective wet etching, or a combination thereof) that etches the materials in dummy gate structures 140 (referring to FIG. 5B) at a faster etch rate than it etches other materials (e.g., gate spacers 150 and/or the dielectric material 210), thus resulting in a gate trench GT between corresponding gate spacers 150, with the sacrificial layers 121, 123, and 125 (referring to FIG. 5B) exposed in the gate trench GT. Subsequently, the sacrificial layers 121, 123, and 125 (referring to FIG. 5B) in the gate trench GT are etched by using another selective etching process that etches the sacrificial layers 121, 123, and 125 (referring to FIG. 5B) at a faster etch rate than it etches the layers 122 and 124, thus respectively forming openings/spaces O1 between the channel layers 122 and between a bottommost one of the channel layers 122 and the substrate portion 112, openings/spaces O3 between the channel layer 124, and an openings/space O2 between the topmost one of the bottom channel layers 122 and the bottommost one of the top channel layers 124. The openings/spaces O1-O3 may expose the sidewalls of the inner spacers 160. In this way, the channel layers 122 become nanosheets suspended over the substrate 110 and between the source/drain epitaxial structures 180, and the channel layers 124 become nanosheets suspended over the substrate 110 and between the source/drain epitaxial structures 200. This step is also called a channel release process.

At this interim processing step, the openings/spaces O1-O3 surrounding the nanosheets 122 and 124 may be filled with ambient environment conditions (e.g., air, nitrogen, etc). In some embodiments, the nanosheets 122 and 124 can be interchangeably referred to as nanowires, nanoslabs and nanorings, depending on their geometry. For example, in some other embodiments, the channel layers 122 and 124 may be trimmed to have a substantial rounded shape (i.e., cylindrical) due to the selective etching process for completely removing the sacrificial layers 121, 123, and 125 (referring to FIG. 5B). In that case, the resultant channel layers 122 and 124 can be called nanowires.

In some embodiments, the sacrificial layers 121, 123, and 125 (referring to FIG. 5B) are SiGe and the channel layers 122 and 124 are silicon allowing for the selective removal of the sacrificial layers 121, 123, and 125 (referring to FIG. 5B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ is removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 121, 123, and 125 (referring to FIG. 5B) are removed. Moreover, because oxidation rate of Si is much lower (sometimes 30 times lower) than oxidation rate of SiGe, the channel layers 122 and 124 may remain substantially intact during the channel release process.

Reference is made to FIGS. 7A and 7D. FIG. 7D is an enlarged view of a portion of FIG. 7B. Replacement gate structures 220 and 230 are formed in the gate trench GT to respectively surround each of the nanosheets 122 and 124 suspended in the gate trench GT. The gate structures 220 and 230 may be final gates of GAA FETs. The final gate structures may be a high-k/metal gate stack, however other compositions are possible. In some embodiments, the gate structure 220 forms the gate associated with the multi-channels provided by the plurality of nanosheets 122, and the gate structure 230 forms the gate associated with the multi-channels provided by the plurality of nanosheets 124. For example, the high-k/metal gate structure 220 is formed within the openings/spaces O1 and O2 provided by the release of nanosheets 122, and the high-k/metal gate structure 230 is formed within the openings/spaces O2 and O3 provided by the release of nanosheets 124. The high-k/metal gate structures 220 may be between the channel layers 122 and between the bottommost one of the channel layers 122 and the substrate portion 112, and surrounded by the inner spacers 160. The high-k/metal gate structures 220 may be between the channel layers 124 and surrounded by the inner spacers 160. Each of the high-k/metal gate structures 220 and 230 have a portion between the topmost one of the bottom channel layers 122 and the bottommost one of the top channel layers 124.

The high-k/metal gate structure 220 may include a gate dielectric layer 222 formed around the nanosheets 122, a work function metal layer 224 formed around the gate dielectric layer 222, and a gate fill metal 226 formed around the work function metal layer 224 and filling a remainder of gate trenches GT. And, the high-k/metal gate structure 230 may include a gate dielectric layer 232 formed around the nanosheets 132, a work function metal layer 234 formed around the gate dielectric layer 232, and a gate fill metal 236 formed around the work function metal layer 234 and filling a remainder of gate trenches GT. Formation of the high-k/metal gate structures 220 may include one or more deposition processes to form various gate materials, followed by an etching processes to remove excessive gate materials, resulting in the high-k/metal gate structures 220 having top surfaces lower than a bottom surface of the bottommost one of the channel layer 124. Formation of the high-k/metal gate structures 230 may include one or more deposition processes to form various gate materials after the formation of the high-k/metal gate structures 220, followed by a planarization processes (e.g., chemical mechanical polish process) to remove excessive gate materials, resulting in the high-k/metal gate structures 230 having top surfaces level with a top surface of the dielectric material 210. Thus, transistors (e.g., GAA FET) are formed, and the high-k/metal gate structure 220 and 230 surrounds each of the nanosheets 122 and 124, and thus are referred to as gates of the transistors (e.g., GAA FET).

The gate dielectric layer 222 and 232 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the layers 122 and 124 and the substrate portion 112 exposed in the gate trenches GT are oxidized into silicon oxide to form interfacial layer 252. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the interfacial layer and/or the high-k gate dielectric layer of the gate dielectric layer 222 may include a thickness different from that the interfacial layer and/or the high-k gate dielectric layer of the gate dielectric layer 232. In some other embodiments, the interfacial layer and/or the high-k gate dielectric layer of the gate dielectric layer 222 may include the same thickness as the interfacial layer and/or the high-k gate dielectric layer of the gate dielectric layer 232.

In some embodiments, the work function metal layers 224 and 234 provide a suitable work function for the high-k/metal gate structures 220 and 230, respectively. In some embodiments, the work function metal layer 224 may include a material different from that of the work function metal layer 234. In the present embodiments, for forming a complementary field-effect transistor (CFET), an n-type GAA FET is stacked over a p-type GAA FET. For the p-type GAA FET, the work function metal layer 224 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. On the other hand, for the n-type GAA FET, the work function metal layer 234 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. In some alternative embodiments of CFET, a p-type GAA FET is stacked over an n-type GAA FET. In such embodiments, the work function metal layer 224 may include one or more n-type work function metal layers, and the work function metal layer 234 may include one or more p-type work function metal layers. In some other embodiments, the work function metal layers 224 and 234 may include a same material. In some embodiments, the gate fill metals 226 and 236 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. In some embodiments, the gate fill metals 226 and 236 may include a same material. The gate fill metals 226 and 236 may be deposited by one deposition process with no interface therebetween.

The formed high-k/metal gate structure 220 may have a height MGH_P between the channel layers 122 and between the bottommost channel layer 122 and the substrate portion 112. The formed high-k/metal gate structure 230 may have a height MGH_N between the channel layers 124 and a height MGH_Out over the topmost one of the channel layers 124. The formed high-k/metal gate structures 220 and 230 may have a height MGH_NP between the topmost one of the channel layers 122 and the bottommost one of the channel layers 124. Owing to the thickness variation of the sacrificial layers 121, 123, and 125 (referring to FIG. 1), the height MGH_NP is greater than the height MGH_N and the height MGH_P. For example, the height MGH_NP may be substantially equal to a combination of the height MGH_N and the height MGH_P. The height MGH_P may be less than, substantially equal to, or greater than the height MGH_N.

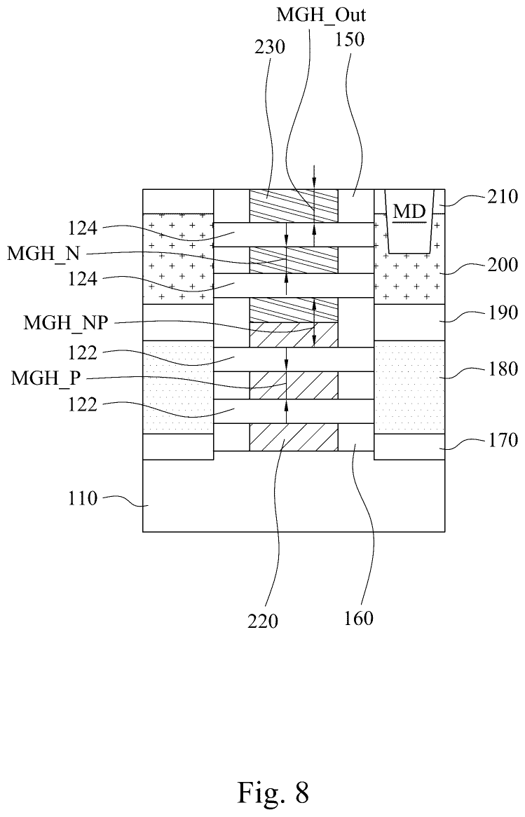

Reference is made to FIG. 8. A source/drain contact MD is formed for providing electrical connection to the source/drain epitaxial structure 200. The formation of the source/drain contact MD includes etching a source/drain contact opening in the dielectric material 210 to expose a frontside of the source/drain epitaxial structure 200, and depositing one or more conductive materials into the source/drain contact opening, followed by a planarization process (e.g., CMP process) to remove an excess portion of the conductive material outside the source/drain contact opening. The conductive materials may include TiN, TaN, W, Co, Ru, Al, Cu, other metals, the like, or the combination thereof. A remaining portion of the conductive material forms the source/drain contact MD.

After the planarization process, the high-k/metal gate structures 230 is exposed. In the present embodiments, the planarization process following the deposition of the conductive materials into the source/drain contact opening may also remove a portion of the high-k/metal gate structure 230. Thus, the height MGH_Out of the high-k/metal gate structure 230 may be reduced by the planarization process.

In the present embodiments, by controlling the end point of the planarization process to remove excessive gate materials after the formation of the high-k/metal gate structures 230 and by controlling the end point of the planarization process following the deposition of the conductive materials into the source/drain contact opening, the height MGH_Out of the high-k/metal gate structure 230 is less than the height MGH_NP. For example, the height MGH_Out may be in a range from about 4 nanometers to about 18 nanometers, while the height MGH_N and the height MGH_P may be in a range from about 5 nanometers to about 20 nanometers. In the present embodiments, the height MGH_Out is greater than the height MGH_N or MGH_P and less than the height MGH_NP. In some embodiments, the height MGH_Out is equal to or less than the height MGH_N or MGH_P and less than the height MGH_NP.

In some embodiments, after etching the source/drain contact opening in the dielectric material 210, and prior to depositing the conductive materials into the source/drain contact opening, a metal alloy layer is formed on a portion of the source/drain epitaxial structures 200 exposed by the source/drain contact opening. The metal alloy layer may be a silicide layer formed by a silicide (salicide) process. The silicide process converts a surface portion of the source/drain epitaxial structure 200 into the silicide contacts. Silicide processing involves deposition of a metal that undergoes a silicidation reaction with silicon (Si). In order to form silicide contacts on the source/drain epitaxial structure 200, a metal material is blanket deposited on the exposed frontside of the source/drain epitaxial structure 200. After heating the wafer to a temperature at which the metal reacts with the silicon of the source/drain epitaxial structure 200 to form contacts, unreacted metal is removed. The silicide contacts remain over the frontside of the source/drain epitaxial structure 200, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer may include germanium.

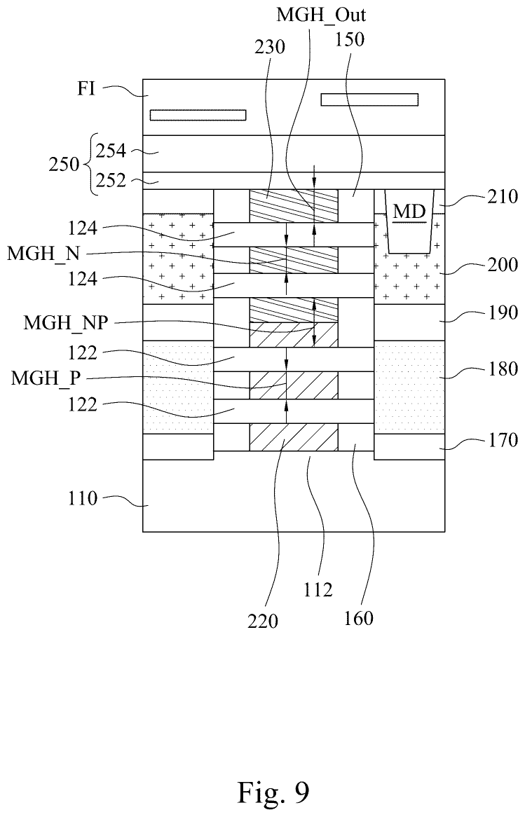

Reference is made to FIG. 9. A dielectric material 250 is formed over the source/drain contact MD and the high-k/metal gate structure 220. The dielectric material 250 may include a etch stop layer 252 and an ILD layer 254 over the etch stop layer 252. In some examples, the etch stop layer 252 includes a silicon nitride layer, silicon oxide layer, a silicon oxynitride layer, and/or other suitable. The ILD layer 254 is then deposited over the etch stop layer 252. In some embodiments, the ILD layer 254 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the etch stop layer 252. The ILD layer 254 may be deposited by a CVD process or other suitable deposition technique.

A front-side multilayer interconnection (MLI) structure FI may be formed over the dielectric material 250. The front-side MLI structure FI may include a plurality of front-side metallization layers. The number of front-side metallization layers may vary according to design specifications of the integrated circuit. The front-side metallization layers each comprise a front-side inter-metal dielectric (IMD) layer, one or more horizontal interconnects, such as front-side metal lines, respectively extending horizontally or laterally in the front-side IMD layer, and vertical interconnects, such as front-side conductive vias, respectively extending vertically in the front-side IMD layer.

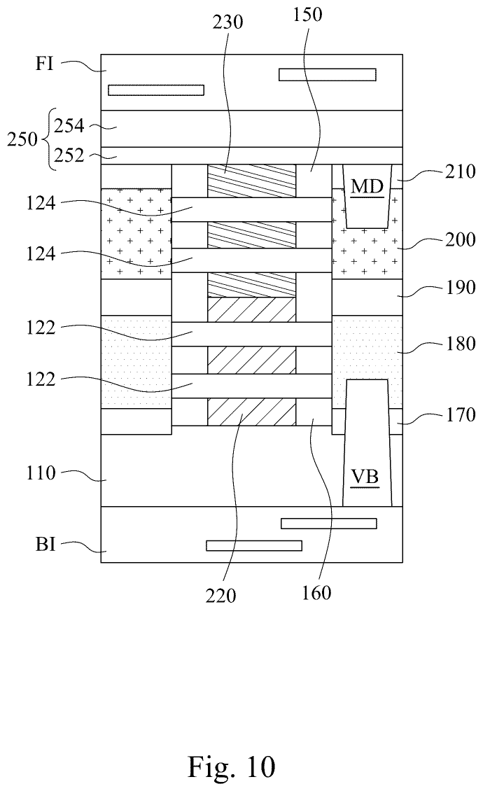

Reference is made to FIG. 10. A backside source/drain contact VB is formed for providing electrical connection to the source/drain epitaxial structure 180. The formation of the backside source/drain contact VB includes etching a backside source/drain contact opening in the substrate 110 and the bottom isolation layer 170 to expose a backside of the source/drain epitaxial structure 180, and depositing one or more conductive materials into the backside source/drain contact opening, followed by a planarization process on a backside of the substrate 11 to remove an excess portion of the conductive material outside the backside source/drain contact opening. The conductive materials may include TiN, TaN, W, Co, Ru, Al, Cu, other metals, the like, or the combination thereof. A remaining portion of the conductive material forms the backside source/drain contact VB.

In some embodiments, after etching the backside source/drain contact opening in the substrate 110 and the bottom isolation layer 170, and prior to depositing the conductive materials into the backside source/drain contact opening, a metal alloy layer is formed on a portion of the source/drain epitaxial structures 180 exposed by the backside source/drain contact opening. The metal alloy layer may be a silicide layer formed by a silicide (salicide) process. The silicide process converts a backside surface portion of the source/drain epitaxial structure 180 into the silicide contacts. Silicide processing involves deposition of a metal that undergoes a silicidation reaction with silicon (Si). In order to form silicide contacts on the source/drain epitaxial structure 180, a metal material is blanket deposited on the exposed backside of the source/drain epitaxial structure 180. After heating the wafer to a temperature at which the metal reacts with the silicon of the source/drain epitaxial structure 180 to form contacts, unreacted metal is removed. The silicide contacts remain over the backside of the source/drain epitaxial structure 180, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer may include germanium.

A back-side multilayer interconnection (MLI) structure BI may be formed over the backside of the backside source/drain contact VB. The back-side MLI structure BI may include a plurality of back-side metallization layers. The number of back-side metallization layers may vary according to design specifications of the integrated circuit. The back-side metallization layers each comprise a back-side inter-metal dielectric (IMD) layer, one or more horizontal interconnects, such as back-side metal lines, respectively extending horizontally or laterally in the back-side IMD layer, and vertical interconnects, such as back-side conductive vias, respectively extending vertically in the back-side IMD layer.

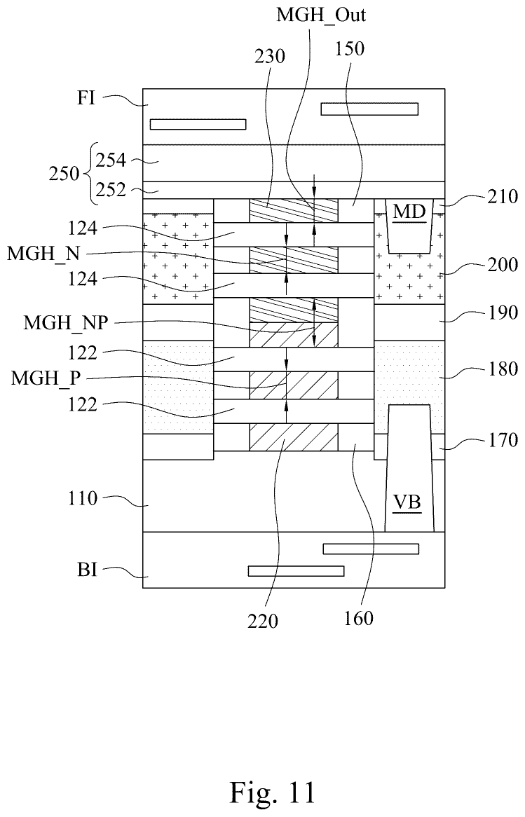

FIG. 11 is a cross-sectional view of a semiconductor device in accordance with some embodiments of the present disclosure. Details of the present embodiments are similar to those illustrated in FIGS. 1-10, except that by controlling the end point of the planarization process to remove excessive gate materials after the formation of the high-k/metal gate structures 230 and by controlling the end point of the planarization process following the deposition of the conductive materials into the source/drain contact opening, the height MGH_Out of the high-k/metal gate structure 230 can be substantially equal to or less than the height MGH_N or height MGH_P, and less than the height MGH_NP. Other details of the present embodiments are similar to those illustrated above, and therefore not repeated herein.

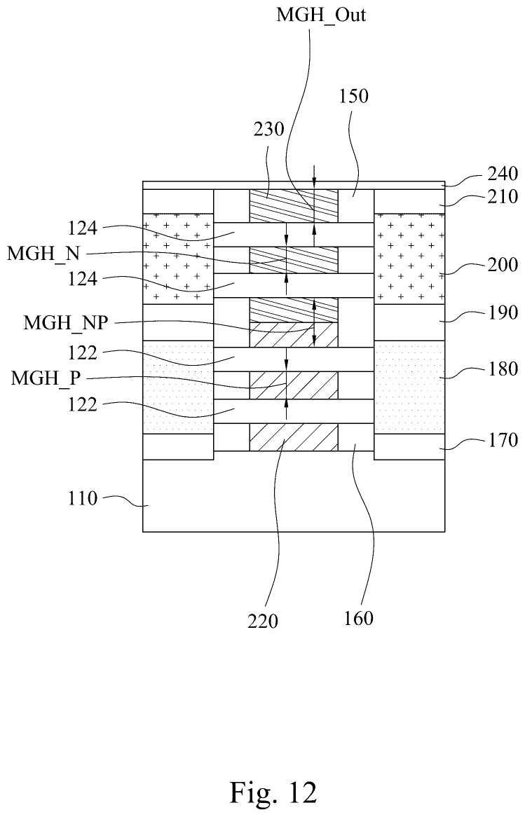

FIGS. 12-14 illustrate schematic views of intermediate stages in the manufacture of a semiconductor device in accordance with some embodiments of the present disclosure. Details of the present embodiments are similar to those illustrated in FIGS. 1-10, except that a top surface of the source/drain contact MD is higher than a top surface of the high-k/metal gate structure 230. It is understood that additional steps may be provided before, during, and after the steps shown in FIGS. 12-14, and some of the steps described below can be replaced or eliminated for additional embodiments of the method. The order of the operations/processes may be interchangeable.

Reference is made to FIG. 12. In the present embodiments, by controlling the end point of the planarization process to remove excessive gate materials after the formation of the high-k/metal gate structures 230 (referring to FIG. 7B), the height MGH_Out of the high-k/metal gate structure 230 is less than the height MGH_NP.

After the formation of the high-k/metal gate structures 220 and 230 (referring to FIG. 7B) and prior to the formation of the source/drain contact MD (referring to FIG. 8), a middle etch stop layer 240 is deposited over the dielectric material 210 and the high-k/metal gate structure 230. The middle etch stop layer 240 may include one or more suitable dielectric materials, such as silicon oxide, silicon nitride, the like, or the combination thereof.

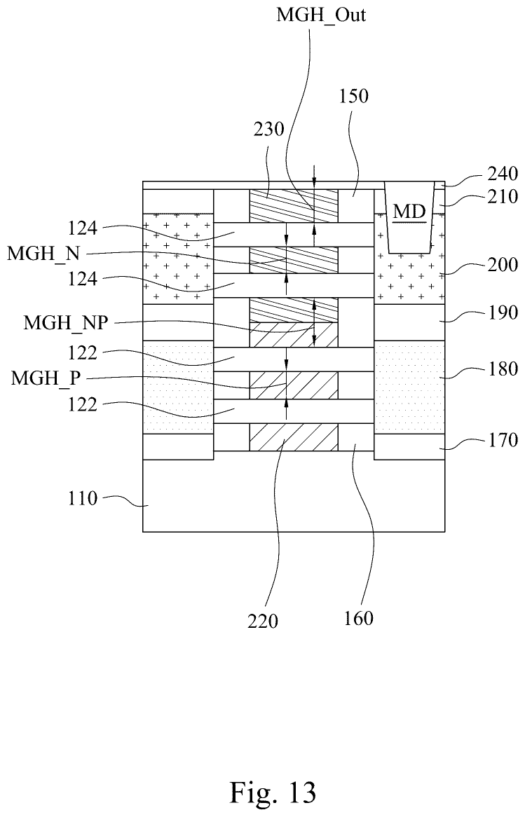

Reference is made to FIG. 13. A source/drain contact MD is formed. The formation of the source/drain contact MD includes etching a source/drain contact opening in the dielectric material 210 and the middle etch stop layer 240 to expose a frontside of the source/drain epitaxial structure 200, and depositing one or more conductive materials into the source/drain contact opening, followed by a planarization process (e.g., CMP process) to remove an excess portion of the conductive material outside the source/drain contact opening. The conductive materials may include TiN, TaN, W, Co, Ru, Al, Cu, other metals, the like, or the combination thereof. A remaining portion of the conductive material forms the source/drain contact MD.

In the present embodiments, the planarization process may stop over the middle etch stop layer 240. Thus, the height MGH_Out of the high-k/metal gate structure 230 may not be changed by the planarization process. After the planarization process, the high-k/metal gate structures 230 remains being covered by the middle etch stop layer 240, and the height MGH_Out of the high-k/metal gate structure 230 is less than the height MGH_NP. In the present embodiments, the height MGH_Out is greater than the height MGH_N or MGH_P and less than the height MGH_NP. In some alternative embodiments, the height MGH_Out is equal to or less than the height MGH_N or MGH_P and less than the height MGH_NP.

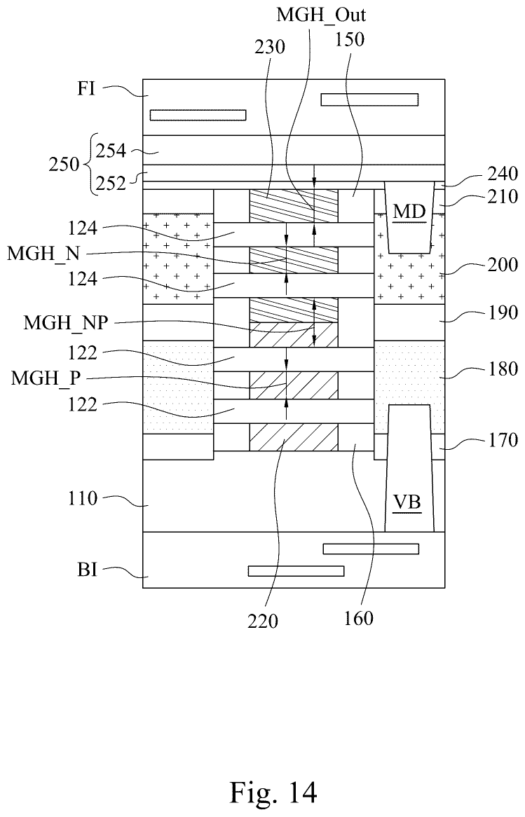

Reference is made to FIG. 14. The dielectric material 250 is formed on the frontside of the gate structure 230 and the frontside of the source/drain contact MD, and the front-side MLI structure FI is formed on the dielectric material 250. The backside source/drain contact VB is formed on the backside of the source/drain epitaxial structures 180, and then the back-side MLI structure BI is formed on the backside of the backside source/drain contact VB. Other details of the present embodiments are similar to those illustrated above, and therefore not repeated herein.

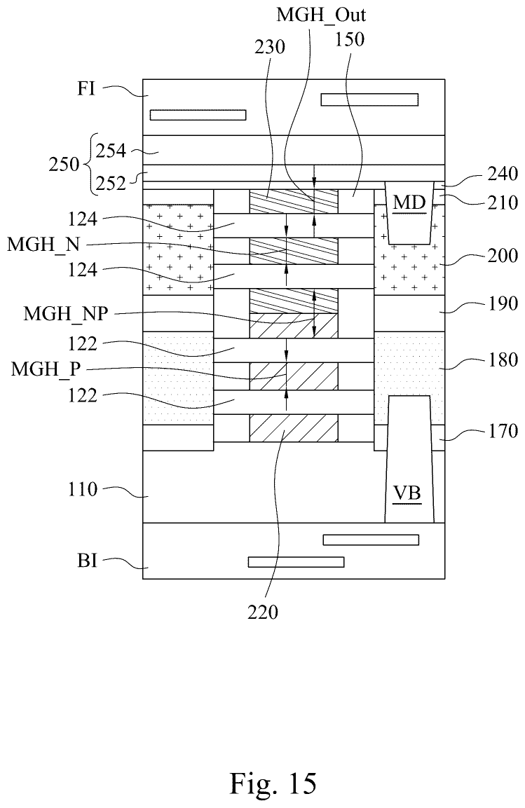

FIG. 15 is a cross-sectional view of a semiconductor device in accordance with some embodiments of the present disclosure. Details of the present embodiments are similar to those illustrated in FIGS. 12-14, except that by controlling the end point of the planarization process to remove excessive gate materials after the formation of the high-k/metal gate structures 230, the height MGH_Out of the high-k/metal gate structure 230 can be substantially equal to or less than the height MGH_N or height MGH_P, and less than the height MGH_NP. Other details of the present embodiments are similar to those illustrated above, and therefore not repeated herein.

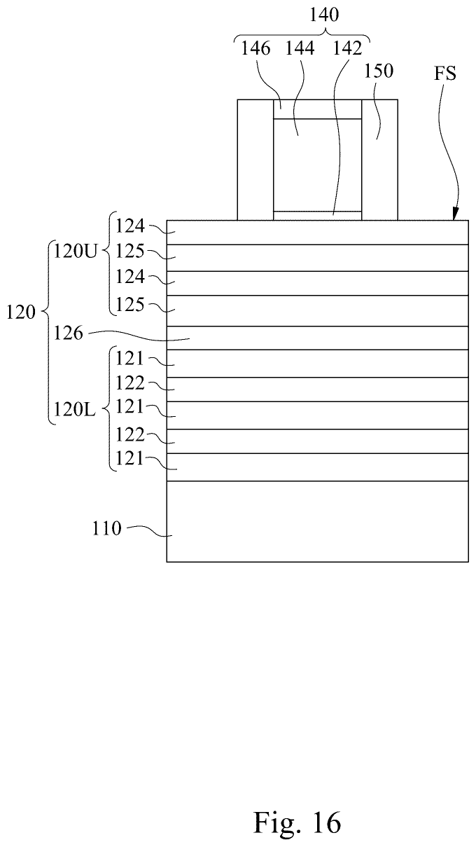

FIGS. 16-22B illustrate cross-sectional views of intermediate stages in the manufacture of a semiconductor device in accordance with some embodiments of the present disclosure. Details of the present embodiments are similar to those illustrated in FIGS. 1-10, except that an isolation layer DL1 is formed between the high-k/metal gate structures 220 and 230. It is understood that additional steps may be provided before, during, and after the steps shown in FIGS. 16-22B, and some of the steps described below can be replaced or eliminated for additional embodiments of the method. The order of the operations/processes may be interchangeable.

Reference is made to FIG. 16. An epitaxial stack 120 is formed over a substrate 110. The epitaxial stack 120 includes a lower epitaxial stack 120L, an interlayer sacrificial layer 126, and an upper epitaxial stack 120U stacked in a sequence over the substrate 110. The lower epitaxial stack 120L includes lower sacrificial layers 121 and lower channel layers 122 alternately arranged with each other. The upper epitaxial stack 120U includes upper semiconductor layers 124 and upper sacrificial layers 125 alternately arranged with each other. The interlayer sacrificial layer 126 is located between the lower epitaxial stack 120L and the upper epitaxial stack 120U.

In some embodiments, the layers 121, 122, 124, 125, and 126 may include SiGe with various semiconductor compositions based on providing differing oxidation and/or etching selectivity properties. For example, the channel layers 122 and 124 are SiₓGe₁₋ₓ, the sacrificial layers 121 and 125 are Si_{y}Ge_{1-y}, and the sacrificial layer 126 is Si_{z}Ge_{1-z}, in which x, y, and z are in a range from 0 to 1, and x>y>z. However, other embodiments are possible including those that provide for the material/compositions having different oxidation rates and/or etch selectivity. In some embodiments, the Si oxidation rate of the channel layers 122 and 124 is less than the SiGe oxidation rate of the sacrificial layers 121 and 125, and the SiGe oxidation rate of the sacrificial layers 121 and 125 is less than the SiGe oxidation rate of the sacrificial layer 126. Other details of the layers 121, 122, 124, 125, and 126 of the epitaxial stack 120 are similar to those illustrated above, and therefore not repeated above.

After the formation of the epitaxial stack 120, the epitaxial stack 120 may be patterned into fins FS, and then one or more dummy gate structures 140 are formed on the epitaxial stack 120. Gate spacers 150 are formed on opposite sidewalls of the dummy gate structures 140.

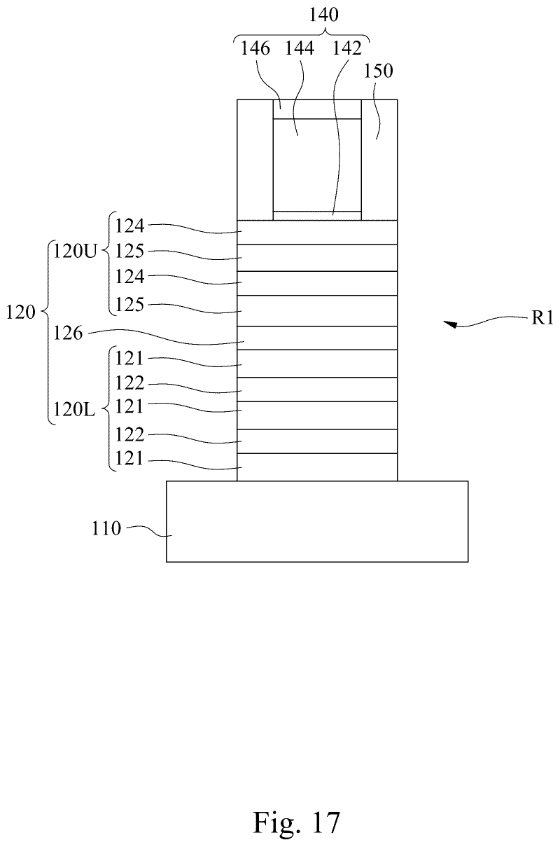

Reference is made to FIG. 17. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS. The recesses R1 may extend through the epitaxial layers 121, 122, 126, 124, and 125. After the anisotropic etching, end surfaces of the epitaxial layers 121, 122, 126, 124, and 125 are exposed and aligned with respective outermost sidewalls of the gate spacers 150, due to the anisotropic etching.

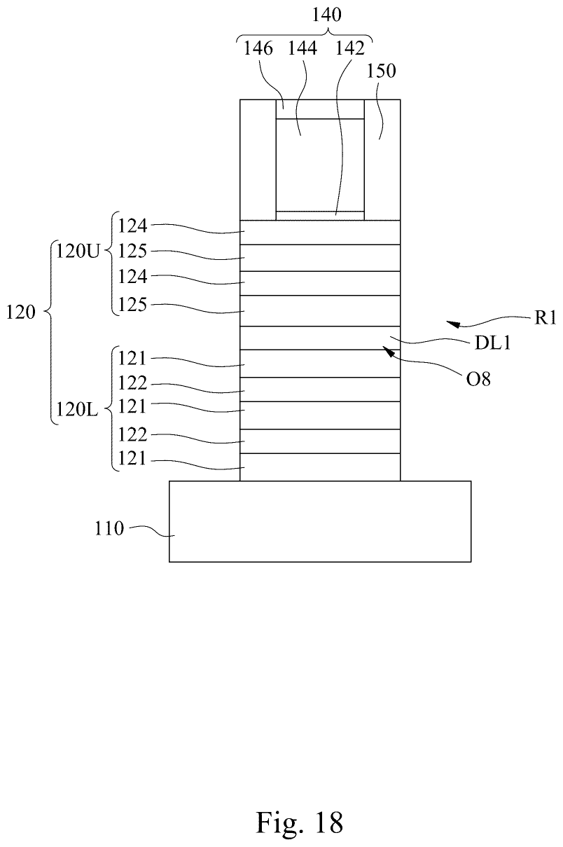

Reference is made to FIG. 18. The sacrificial layer 126 (referring to FIG. 17) is replaced with the isolation layer DL1. For example, the sacrificial layer 126 (referring to FIG. 17) is removed by using suitable selective etching process resulting in an opening/space O8 between the lower epitaxial stack 120L and the upper epitaxial stack 120U. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. Thus, the layers 121, 122, 124, and 125 may have a higher etch resistance to the selective etching process than that of the sacrificial layer 126.

An isolation layer DL1 is formed in the opening/space O8. The isolation layer DL1 may include a dielectric material, such as SiOₓ, SiON, SiOC, SiN, SiCN, or SiOCN. Formation of the isolation layer DL1 may include depositing a dielectric material layer into the opening/space O8, followed by an anisotropic etching process to trim the deposited dielectric material layer. Through the anisotropic etching process, only portions of the deposited dielectric material layer that fill the opening/space O8 are left.

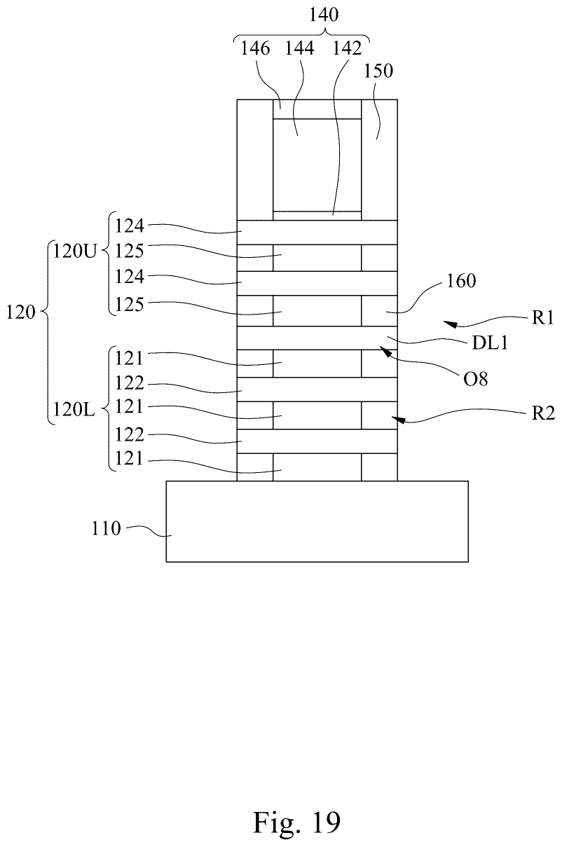

Reference is made to FIG. 19. The sacrificial layers 121 and 125 are laterally or horizontally recessed by using suitable selective etching process, resulting in lateral/sidewall recesses R2 vertically between corresponding channel layers 122 and 124. Inner spacers 160 are formed in the recesses R2. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left.

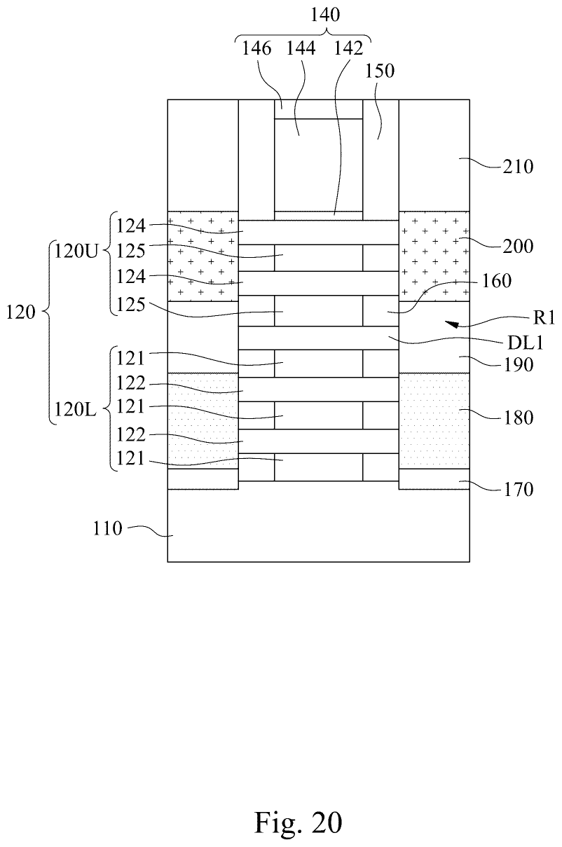

Reference is made to FIG. 20. The bottom isolation layers 170, the source/drain epitaxial structures 180, the middle isolation layers 190, the source/drain epitaxial structures 200, and the dielectric material 210 are formed in the recess R1 in a sequence. The isolation layer DL1 may be in contact with the middle isolation layers 190 between the source/drain epitaxial structures 180 and 200.

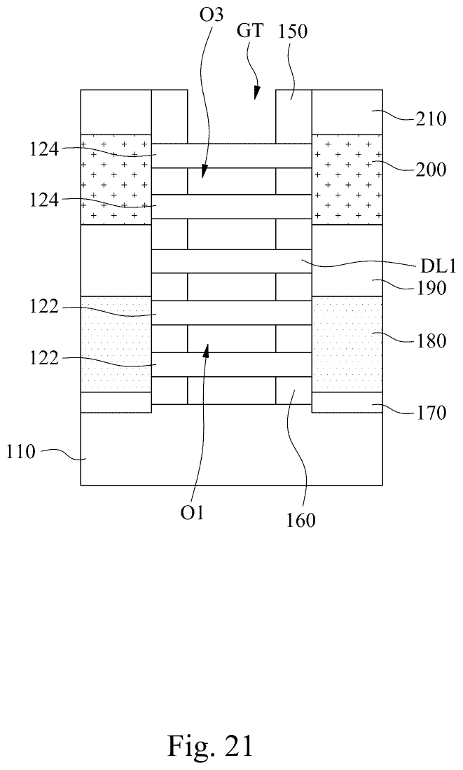

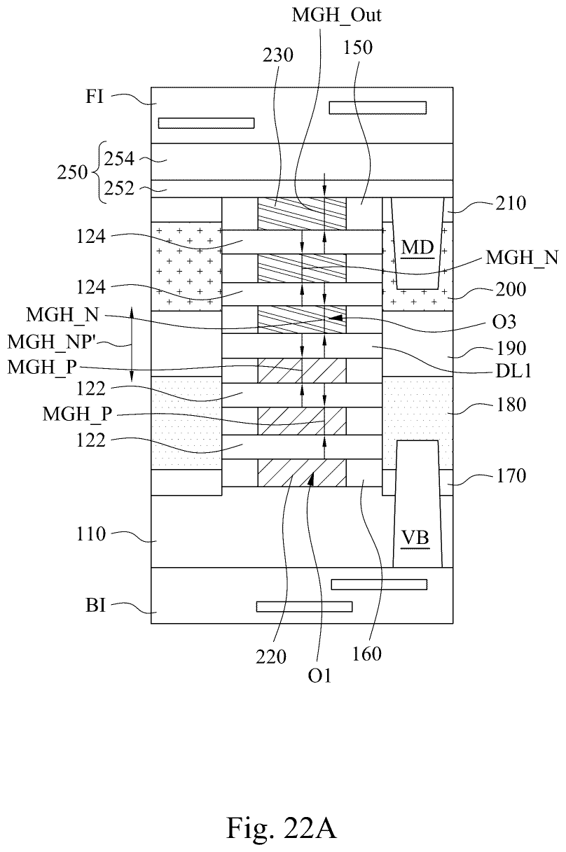

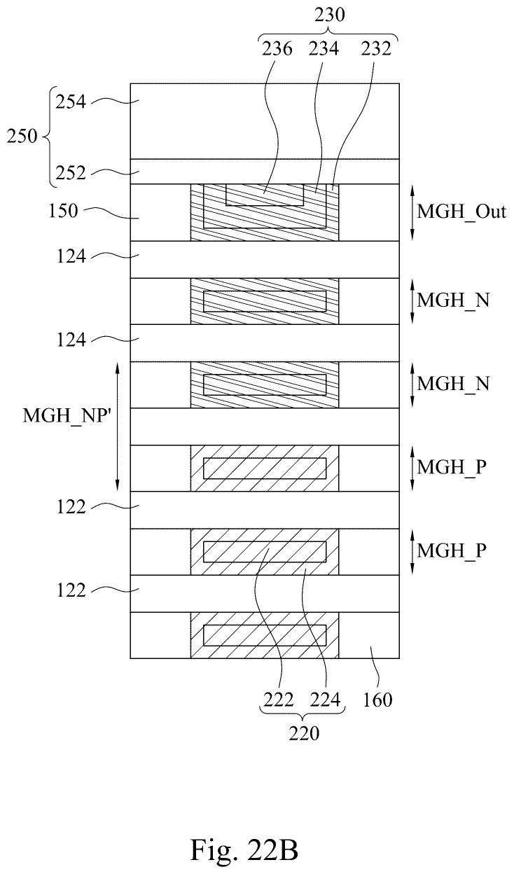

Reference is made to FIGS. 21, 22A, and 22B. The dummy gate structure 140 and the sacrificial layer 121 and 125 (referring to FIG. 20) are replaced with high-k/metal gate structures 220 and 230. In FIG. 21, the dummy gate structure 140 (referring to FIG. 20) is removed, followed by removing the sacrificial layers 121 and 125 (referring to FIG. 20).

In the illustrated embodiments, the dummy gate structure 140 (referring to FIG. 20) is removed by a selective etching process, thus resulting in a gate trench GT between corresponding gate spacers 150, with the sacrificial layers 121 and 125 (referring to FIG. 20) exposed in the gate trench GT. Subsequently, the sacrificial layers 121 and 125 (referring to FIG. 20) in the gate trench GT are etched by using another selective etching process that etches the sacrificial layers 121 and 125 (referring to FIG. 20) at a faster etch rate than it etches the layers 122 and 124, thus forming the openings/spaces O1 and O3. The openings/spaces O1 are formed between the channel layers 122, between a bottommost one of the channel layers 122 and the substrate portion 112, and between a topmost one of the channel layers 122 and the isolation layer DL1. The openings/spaces O3 are formed between the channel layer 124 and between a bottommost one of the channel layers 124 and the isolation layer DL1. The openings/spaces O1 and O3 may expose the sidewalls of the inner spacers 160.

Reference is made to FIGS. 22A and 22B. FIG. 22B is an enlarged view of a portion of FIG. 22A. Replacement gate structures 220 and 230 are formed in the gate trench GT to respectively surround each of the nanosheets 122 and 124 suspended in the gate trench GT. The high-k/metal gate structure 220 is formed within the openings/spaces O1 provided by the release of nanosheets 122, and the high-k/metal gate structure 230 is formed within the openings/spaces O3 provided by the release of nanosheets 124.

The source/drain contact MD is formed on the frontside of the source/drain epitaxial structures 200. The dielectric material 250 is formed on the frontside of the gate structure 230 and the frontside of the source/drain contact MD, and the front-side MLI structure FI is formed on the dielectric material 250. The backside source/drain contact VB is formed on the backside of the source/drain epitaxial structures 180, and then the back-side MLI structure BI is formed on the backside of the backside source/drain contact VB.

In the present embodiments, with the presence of the dielectric layer DL1, the formed high-k/metal gate structures 220 and 230 may have a height MGH_NP′ between the topmost one of the channel layers 122 and the bottommost one of the channel layers 124, the height MGH_NP is greater than the height MGH_N and the height MGH_P. As aforementioned, the height MGH_Out of the high-k/metal gate structure 230 can be less than the height MGH_NP′. In the present embodiments, the height MGH_Out is greater than the height MGH_N or MGH_P and less than the height MGH_NP′. In some alternative embodiments, the height MGH_Out is equal to or less than the height MGH_N or MGH_P and less than the height MGH_NP′. Other details of the present embodiments are similar to those illustrated above, and therefore not repeated herein.

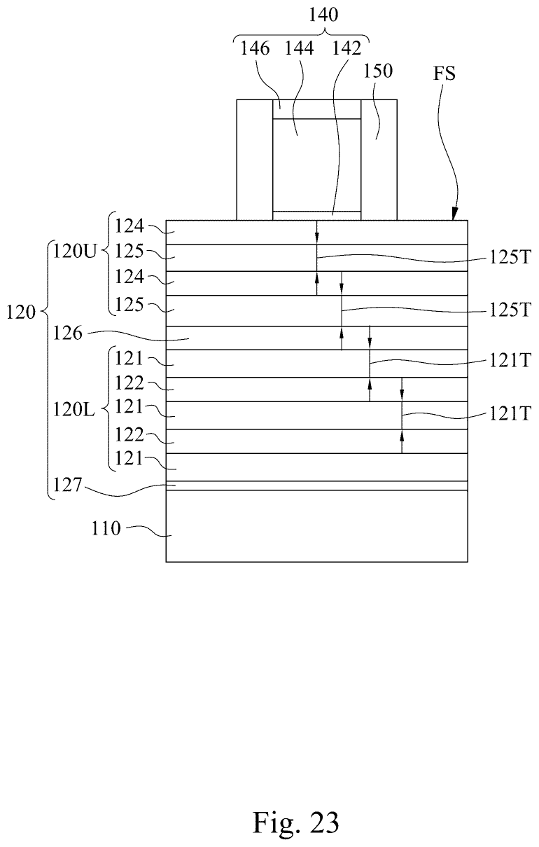

FIGS. 23-29 illustrate schematic views of intermediate stages in the manufacture of a semiconductor device in accordance with some embodiments of the present disclosure. Details of the present embodiments are similar to those illustrated in FIGS. 16-22B, except that an isolation layer DL2 is formed between the high-k/metal gate structure 220 and the substrate 110. It is understood that additional steps may be provided before, during, and after the steps shown in FIGS. 23-29, and some of the steps described below can be replaced or eliminated for additional embodiments of the method. The order of the operations/processes may be interchangeable.

Reference is made to FIG. 23. An epitaxial stack 120 is formed over a substrate 110. The epitaxial stack 120 includes a bottom sacrificial layer 127, a lower epitaxial stack 120L, an interlayer sacrificial layer 126, and an upper epitaxial stack 120U stacked in a sequence over the substrate 110. The lower epitaxial stack 120L includes lower sacrificial layers 121 and lower channel layers 122 alternately arranged with each other. The upper epitaxial stack 120U includes upper semiconductor layers 124 and upper sacrificial layers 125 alternately arranged with each other. The interlayer sacrificial layer 126 is located between the lower epitaxial stack 120L and the substrate 110. The interlayer sacrificial layer 126 is located between the lower epitaxial stack 120L and the upper epitaxial stack 120U.

In some embodiments, the layers 127, 121, 122, 124, 125, and 126 may include SiGe with various semiconductor compositions based on providing differing oxidation and/or etching selectivity properties. For example, the channel layers 122 and 124 are SiₓGe₁₋ₓ, the sacrificial layers 121 and 125 are Si_{y}Ge_{1-y}, the sacrificial layer 126 is Si_{z}Ge_{1-z}, and the sacrificial layer 127 is Si_{w}Ge_{1-w}, in which x, y, z, and w are in a range from 0 to 1, x>y>z or x>y>w, and z can be equal to or different from w. For example, z is greater than w, z is in a range from about 0.45 to about 0.55, and w is in a range from about 0.35 to about 0.45. However, other embodiments are possible including those that provide for the material/compositions having different oxidation rates and/or etch selectivity. In some embodiments, the Si oxidation rate of the channel layers 122 and 124 is less than the SiGe oxidation rate of the sacrificial layers 121 and 125, and the SiGe oxidation rate of the sacrificial layers 121 and 125 is less than the SiGe oxidation rates of the sacrificial layers 126 and 127. In some embodiments, the layers 121, 122, 124, 125, 126, and 127 are intrinsic semiconductor layers, which are not intentionally doped, for example, not having intentionally placed dopants, but rather having a doping resulting from process contaminants. In some embodiments, the layers 121, 122, 124, 125, 126, and 127 are substantially dopant-free (i.e., having an extrinsic dopant concentration from about 0 cm⁻³ to about 1×10¹⁸ cm⁻³), where for example, no intentional doping is performed during the epitaxial growth process. Other details of the layers 121, 122, 124, 125, 126, and 127 of the epitaxial stack 120 are similar to those illustrated above, and therefore not repeated above.

After the formation of the epitaxial stack 120, the epitaxial stack 120 may be patterned into fins FS, and then one or more dummy gate structures 140 are formed on the epitaxial stack 120. Gate spacers 150 are formed on opposite sidewalls of the dummy gate structures 140.

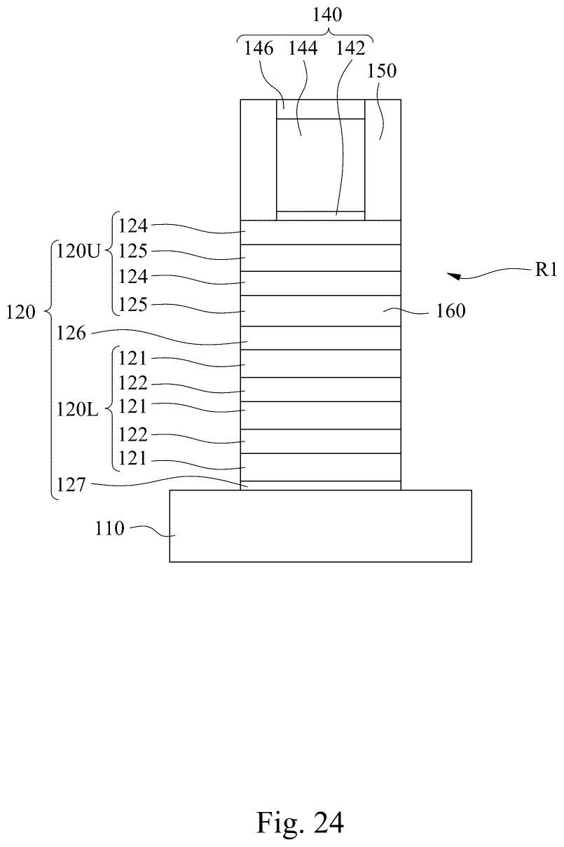

Reference is made to FIG. 24. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS. The recesses R1 may extend through the epitaxial layers 127, 121, 122, 126, 124, and 125. After the anisotropic etching, end surfaces of the epitaxial layers 127, 121, 122, 126, 124, and 125 are exposed and aligned with respective outermost sidewalls of the gate spacers 150, due to the anisotropic etching.

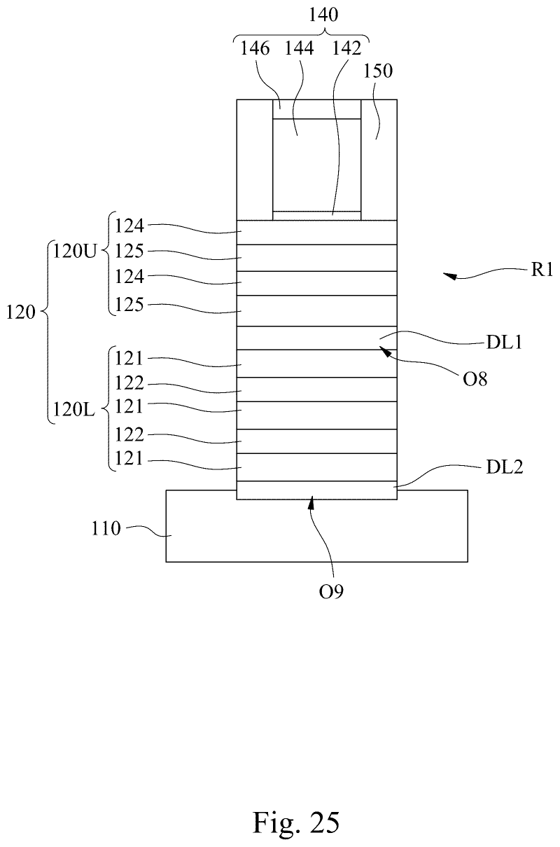

Reference is made to FIG. 25. The sacrificial layers 126 and 127 (referring to FIG. 23) are replaced with the isolation layer DL1. For example, the sacrificial layer 126 and 127 (referring to FIG. 23) are removed by using suitable selective etching process resulting in an opening/space O8 between the lower epitaxial stack 120L and the upper epitaxial stack 120U and an opening/space O9 between the lower epitaxial stack 120L and the substrate 110. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. Thus, the layers 121, 122, 124, and 125 may have a higher etch resistance to the selective etching process than that of the sacrificial layers 126 and 127 (referring to FIG. 23).

Isolation layers DL1 and DL2 are formed in the opening/spaces O8 and O9. The isolation layers DL1 and DL2 may include a dielectric material, such as SiN, SiO₂, SiON, SiCN, SiCON, SiCO, high-k dielectrics (e.g., HfO, AlO, etc.), other low-k dielectric materials, the like, or the combination thereof. The isolation layer DL1/DL2 may be a single-layer or a multi-layer structure. Formation of the isolation layers DL1 and DL2 may include depositing a dielectric material layer into the opening/spaces O8 and O9, followed by an anisotropic etching process to trim the deposited dielectric material layer. Through the anisotropic etching process, only portions of the deposited dielectric material layer that fill the opening/spaces O8 and O9 are left.

In some embodiments, by designing the sacrificial layers 126 and 127 (referring to FIG. 23) with different semiconductor compositions, the sacrificial layers 126 and 127 (referring to FIG. 23) may be removed by different selective etching process. In some embodiments, the sacrificial layer 127 is replaced with the isolation layer DL2 after the sacrificial layer 126 is replaced with the isolation layer DL1. For example, the sacrificial layer 126 (referring to FIG. 23) may be removed by a first selective etching process to leave an opening/space O8 between the lower epitaxial stack 120L and the upper epitaxial stack 120U, and the isolation layer DL1 is then formed in the opening/space O8 by a first deposition process of a first dielectric material and a first anisotropic process to trim the first dielectric material. After forming the isolation layer DL1 in the opening/space O8, the sacrificial layer 127 (referring to FIG. 23) may be removed by a second selective etching process to leave an opening/space O9 between the lower epitaxial stack 120L and the substrate 110, and the isolation layer DL2 is then formed in the opening/space O9 by a second deposition process of a second dielectric material and a second anisotropic process to trim the second dielectric material. The first dielectric material can be the same as or different from the second dielectric material. In some alternative embodiments, the sacrificial layer 126 is replaced with the isolation layer DL1 after the sacrificial layer 127 is replaced with the isolation layer DL2.

In some other embodiments, by designing the sacrificial layers 126 and 127 (referring to FIG. 23) with a same semiconductor composition, the sacrificial layers 126 and 127 (referring to FIG. 23) may be removed by a same selective etching process to leave the opening/spaces O8 and O9, and then the isolation layers DL1 and DL2 are formed into the opening/spaces O8 and O9 by a same deposition process of a dielectric material and a anisotropic process to trim the dielectric material.

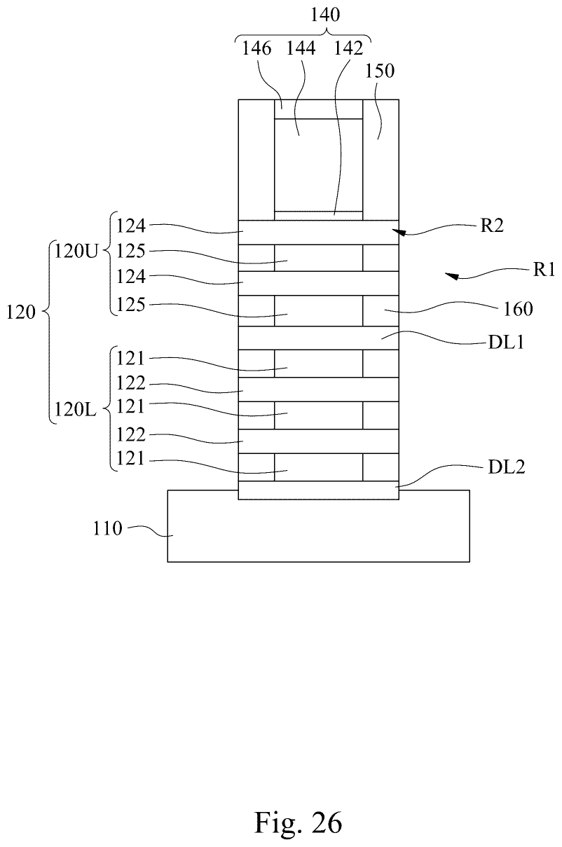

Reference is made to FIG. 26. The sacrificial layers 121 and 125 are laterally or horizontally recessed by using suitable selective etching process, resulting in lateral/sidewall recesses R2 vertically between corresponding channel layers 122 and 124. Inner spacers 160 are formed in the recesses R2. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left.

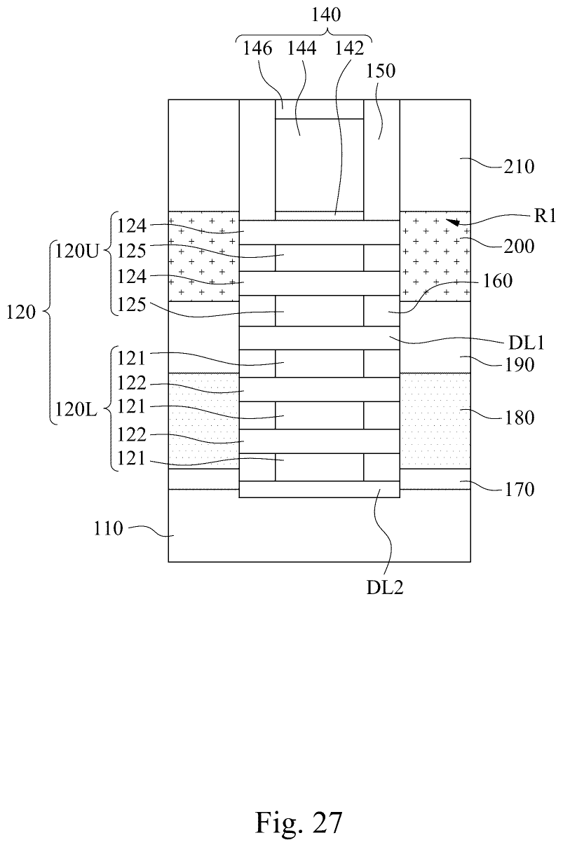

Reference is made to FIG. 27. The bottom isolation layers 170, the source/drain epitaxial structures 180, the middle isolation layers 190, the source/drain epitaxial structures 200, and the dielectric material 210 are formed in the recess R1 in a sequence. The isolation layer DL1 may be in contact with the middle isolation layers 190 between the source/drain epitaxial structures 180 and 200. The isolation layer DL1 may be in contact with the bottom isolation layers 170 below the source/drain epitaxial structures 180.

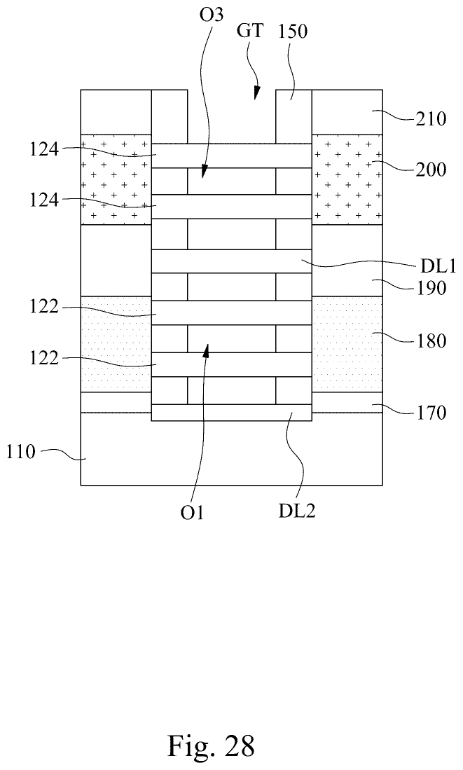

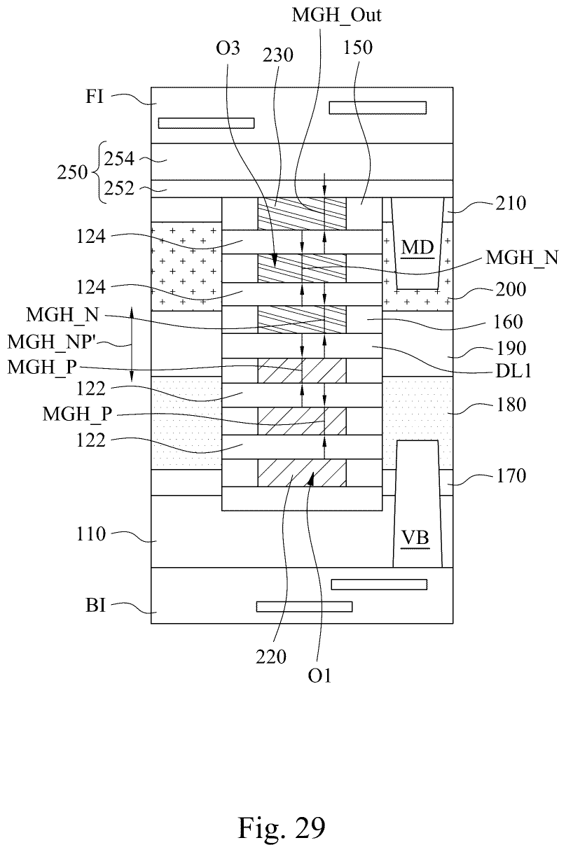

Reference is made to FIGS. 28 and 29. The dummy gate structure 140 and the sacrificial layer 121 and 125 (referring to FIG. 27) are replaced with high-k/metal gate structures 220 and 230. In FIG. 28, the dummy gate structure 140 (referring to FIG. 27) is removed, followed by removing the sacrificial layers 121 and 125 (referring to FIG. 27).

In the illustrated embodiments, the dummy gate structure 140 (referring to FIG. 20) is removed by a selective etching process, thus resulting in a gate trench GT between corresponding gate spacers 150, with the sacrificial layers 121 and 125 (referring to FIG. 27) exposed in the gate trench GT. Subsequently, the sacrificial layers 121 and 125 (referring to FIG. 27) in the gate trench GT are etched by using another selective etching process that etches the sacrificial layers 121 and 125 (referring to FIG. 27) at a faster etch rate than it etches the layers 122 and 124, thus forming the openings/spaces O1 and O3. The openings/spaces O1 are formed between the channel layers 122, between a bottommost one of the channel layers 122 and the isolation layer DL2, and between a topmost one of the channel layers 122 and the isolation layer DL1. The openings/spaces O3 are formed between the channel layer 124 and between a bottommost one of the channel layers 124 and the isolation layer DL1. The openings/spaces O1 and O3 may expose the sidewalls of the inner spacers 160.

Reference is made to FIG. 29. Replacement gate structures 220 and 230 are formed in the gate trench GT to respectively surround each of the nanosheets 122 and 124 suspended in the gate trench GT. The high-k/metal gate structure 220 is formed within the openings/spaces O1 provided by the release of nanosheets 122, and the high-k/metal gate structure 230 is formed within the openings/spaces O3 provided by the release of nanosheets 124. The source/drain contact MD, the dielectric material 250, the front-side MLI structure FI, the backside source/drain contact VB, the back-side MLI structure BI are formed after the gate replacement process.

In the present embodiments, with the presence of the dielectric layer DL1, the formed high-k/metal gate structures 220 and 230 may have a height MGH_NP′ between the topmost one of the channel layers 122 and the bottommost one of the channel layers 124, the height MGH_NP is greater than the height MGH_N and the height MGH_P. As aforementioned, the height MGH_Out of the high-k/metal gate structure 230 can be less than the height MGH_NP′. Other details of the present embodiments are similar to those illustrated above, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One of the advantages is that outer HKMG height is equal to or smaller than inner HKMG height of GAA for low capacitance. Another advantage is that the metal gate heights can be adjusted according to logic cells or SRAM cells.

According to some embodiments of the present disclosure, a method for manufacturing a semiconductor device is provided. The method includes forming an epitaxial stack over a substrate, the epitaxial stack comprising a first epitaxial stack and a second epitaxial stack over the first epitaxial stack, wherein the first epitaxial stack comprises at least one first semiconductor layer and at least one first sacrificial layer alternately arranged with each other, the second epitaxial stack comprises at least one second semiconductor layer and at least one second sacrificial layer alternately arranged with each other; forming a dummy gate structure over the epitaxial stack; replacing the dummy gate structure, the at least one first sacrificial layer, and the at least one second sacrificial layer with a high-k/metal gate structure; and performing a planarization process on the high-k/metal gate structure, such that a first portion of the high-k/metal gate structure over the at least one second semiconductor layer has a height less than a height of a second portion of the high-k/metal gate structure between the at least one first semiconductor layer and the at least one second semiconductor layer.

According to some embodiments of the present disclosure, a method for manufacturing a semiconductor device is provided. The method includes forming an epitaxial stack over a substrate, the epitaxial stack comprising at least one first semiconductor layer, at least one second semiconductor layer above the at least one first semiconductor layer, and a plurality of sacrificial layers alternately arranged with the at least one first semiconductor layer and the at least one second semiconductor layer; removing the sacrificial layers to release the at least one first semiconductor layer and the at least one second semiconductor layer; forming a first high-k/metal gate structure around the at least one first semiconductor layer; forming a second high-k/metal gate structure around the at least one second semiconductor layer; and lowering a top surface of the second high-k/metal gate structure, such that a top portion of the second high-k/metal gate structure over the at least one second semiconductor layer has a height equal to or less than a thickness of the sacrificial layers.

According to some embodiments of the present disclosure, a semiconductor device includes a substrate, a first active region, a first high-k/metal gate structure, a first source/drain epitaxial feature, a second active region, a second high-k/metal gate structure, a second source/drain epitaxial feature, and an isolation structure. The first active region comprises a plurality of first channel layers on the substrate. The first high-k/metal gate structure wraps around the first channel layers. The first source/drain epitaxial feature is on a side of the first channel layers. The second active region comprises a plurality of second channel layers on the substrate. The second high-k/metal gate structure wraps around the second channel layers. The second source/drain epitaxial feature is on a side of the second channel layers. The second source/drain epitaxial feature has a conductivity type opposite to a conductivity type of the first source/drain epitaxial feature. The isolation structure is between the first active region and the second active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming an epitaxial stack over a substrate, the epitaxial stack comprising a first epitaxial stack and a second epitaxial stack over the first epitaxial stack, wherein the first epitaxial stack comprises at least one first semiconductor layer and at least one first sacrificial layer alternately arranged with each other, the second epitaxial stack comprises at least one second semiconductor layer and at least one second sacrificial layer alternately arranged with each other;
forming a dummy gate structure over the epitaxial stack;
replacing the dummy gate structure, the at least one first sacrificial layer, and the at least one second sacrificial layer with a high-k/metal gate structure; and
performing a planarization process on the high-k/metal gate structure, such that a first portion of the high-k/metal gate structure over the at least one second semiconductor layer has a height less than a height of a second portion of the high-k/metal gate structure between the at least one first semiconductor layer and the at least one second semiconductor layer.

2. The method of claim 1, wherein the planarization process is performed such that the height of the first portion of the high-k/metal gate structure is equal to or less than a thickness of the second sacrificial layer.

3. The method of claim 1, wherein the high-k/metal gate structure comprises:
a p-type work function metal layer surrounding the at least one first sacrificial layer; and
a n-type work function metal layer surrounding the at least one second sacrificial layer.

4. The method of claim 3, wherein the second portion of the high-k/metal gate structure between the at least one first semiconductor layer and the at least one second semiconductor layer comprise a portion of the p-type work function metal layer and a portion of the n-type work function metal layer.

5. The method of claim 1, wherein forming the epitaxial stack is performed such that the epitaxial stack further comprises a third sacrificial layer between the first epitaxial stack and the second epitaxial stack, and a thickness of the third sacrificial layer is greater than a thickness of the second sacrificial layer.

6. The method of claim 1, wherein forming the epitaxial stack is performed such that the epitaxial stack further comprises a fourth sacrificial layer between the first epitaxial stack and the second epitaxial stack, and the method further comprises:
replacing the fourth sacrificial layer with a first isolation layer.

7. The method of claim 1, wherein forming the epitaxial stack is performed such that the epitaxial stack further comprises a fifth sacrificial layer between the first epitaxial stack and the substrate, and the method further comprises:
replacing the fifth sacrificial layer with a second isolation layer.

8. The method of claim 1, further comprises:
forming a first source/drain epitaxial feature on a side of the at least one first semiconductor layer;
forming a second source/drain epitaxial feature a side of the at least one second semiconductor layer and above the first source/drain epitaxial feature; and
forming a source/drain contact over the second source/drain epitaxial feature, wherein the planarization process is performed after forming the source/drain contact.

9. The method of claim 8, wherein the planarization process is performed such that a top surface of the high-k/metal gate structure is substantially level with a top surface of the source/drain contact.

10. The method of claim 1, further comprises:
forming a first source/drain epitaxial feature on a side of the at least one first semiconductor layer;
forming a second source/drain epitaxial feature a side of the at least one second semiconductor layer and above the first source/drain epitaxial feature; and
after the planarization process, forming a source/drain contact over the second source/drain epitaxial feature.

11. The method of claim 10, further comprises:
depositing an etch stop layer over the high-k/metal gate structure and the second source/drain epitaxial feature prior to forming the source/drain contact, wherein forming the source/drain contact is performed such that the source/drain contact extends through the etch stop layer, and a top surface of the source/drain contact is higher than a top surface of the high-k/metal gate structure.

12. A method for manufacturing a semiconductor device, comprising:
forming an epitaxial stack over a substrate, the epitaxial stack comprising at least one first semiconductor layer, at least one second semiconductor layer above the at least one first semiconductor layer, and a plurality of sacrificial layers alternately arranged with the at least one first semiconductor layer and the at least one second semiconductor layer;
removing the sacrificial layers to release the at least one first semiconductor layer and the at least one second semiconductor layer;
forming a first high-k/metal gate structure around the at least one first semiconductor layer;
forming a second high-k/metal gate structure around the at least one second semiconductor layer; and
lowering a top surface of the second high-k/metal gate structure, such that a top portion of the second high-k/metal gate structure over the at least one second semiconductor layer has a height equal to or less than a thickness of the sacrificial layers.

13. The method of claim 12, wherein the first high-k/metal gate structure comprises a work function metal different from a work function metal of the second high-k/metal gate structure.

14. The method of claim 12, wherein a gate dielectric layer of the first high-k/metal gate structure has with a thickness different from that of a gate dielectric layer of the second high-k/metal gate structure.

15. A semiconductor device, comprising:
a substrate;
a first active region comprising a plurality of first channel layers on the substrate;
a first high-k/metal gate structure wrapping around the first channel layers;
a first source/drain epitaxial feature on sides of the first channel layers;
a second active region comprising a plurality of second channel layers on the substrate;
a second high-k/metal gate structure wrapping around the second channel layers;
a second source/drain epitaxial feature on sides of the second channel layers, wherein the second source/drain epitaxial feature has a conductivity type opposite to a conductivity type of the first source/drain epitaxial feature; and
an isolation structure between the first active region and the second active region.

16. The semiconductor device of claim 15, wherein a first portion of the first high-k/metal gate structure over a topmost one of the first channel layers has a first height, a second portion of the first high-k/metal gate structure between adjacent two of the first channel layers has a second height, the first height is equal to or less than the second height.

17. The semiconductor device of claim 15, wherein the first active region is above the second active region.

18. The semiconductor device of claim 17, wherein a first portion of the first high-k/metal gate structure over a topmost one of the first channel layers has a first height, the first height is less than a distance between a bottommost one of the first channel layers and a topmost one of the second channel layers.

19. The semiconductor device of claim 18, wherein the first high-k/metal gate structure comprises a first work function metal layer surrounding the first channel layers, the second high-k/metal gate structure comprises a second work function metal layer surrounding the second channel layers, wherein the second work function metal layer comprises a material different from a material of the first work function metal layer.

20. The semiconductor device of claim 15, wherein
the first high-k/metal gate structure comprises a first high-k dielectric layer surrounding the first channel layers, the second high-k/metal gate structure comprises a second high-k dielectric layer surrounding the second channel layers, wherein the second high-k dielectric layer has a thickness different from a thickness of the first high-k dielectric layer.
